(19) United States
(12) Patent Application Publication
(10) Pub. No.: US 2009/0258167 A1
(43) Pub. Date: Oct. 15, 2009

(54) Film Deposition Method and Method for Manufacturing Light-Emitting Element

(75) Inventor: Koichiro Tanaka, Isehara (JP)

Correspondence Address: COOK ALEX LTD, SUITE 2850, 200 WEST ADAMS STREET, CHICAGO, IL, 60606, US

(73) Assignee: Semiconductor Energy Laboratory Co., Ltd.

(21) Appl. No.: 12/422,642

(22) Filed: Apr. 13, 2009

(30) Foreign Application Priority Data
Apr. 15, 2008 (JP) 2008-105559

(51) Int. Cl. C23C 14/28

(52) U.S. Cl. 427/595

(57) ABSTRACT

It is an object to provide a technique that enables transfer by laser irradiation without unevenness while a high degree of vacuum is maintained in the space between a substrate provided with a material layer and a transfer receiving substrate. The present invention relates to a deposition method including the following steps: making a first substrate that has a light-transmitting property and has a light absorption layer and a material layer having a light-emitting material face a second substrate; placing the second substrate facing the first substrate in an inner space of a vacuum jig; reducing pressure in the inner space of the vacuum jig; and emitting a laser beam to a second surface which is a surface on a side opposite to the first surface of the first substrate, and transferring the material layer in a region irradiated with the laser beam to the second substrate. In addition, the present invention relates to a method for manufacturing a light-emitting element using the deposition method.

### BACKGROUND OF THE INVENTION

1. Field of the Invention

One embodiment of the present invention disclosed in this specification relates to a film deposition method and a method for manufacturing a light-emitting element.

2. Description of the Related Art

Light-emitting elements using an organic compound as a light emitter, which are characterized by thinness, lightweight, fast response, and direct current low voltage driving, have been applied to next-generation flat panel displays. Of display devices, ones having light-emitting elements arranged in matrix are considered to be particularly superior to conventional liquid crystal display devices for their wide viewing angle and excellent visibility.

It is said that, as for a light-emitting mechanism of a light-emitting element, an EL layer is sandwiched between a pair of electrodes and voltage is applied to the EL layer, and thus electrons injected from a cathode and holes injected from an anode are recombined in an emission center of the EL layer to form molecular excitons, and the molecular excitons release energy when returning to a ground state; thus, light is emitted. An excited singlet state and an excited triplet state are known as an excited state, and it is believed that light can be emitted through either state.

An EL layer included in a light-emitting element includes at least a light-emitting layer. In addition, the EL layer can have a stacked structure including a hole-injecting layer, a hole-transporting layer, an electron-transporting layer, an electron-injecting layer, and/or the like, in addition to the light-emitting layer.

In addition, an EL material for forming an EL layer is broadly classified into a low molecular (monomer) material and a high molecular (polymer) material. In general, a film of a low molecular material is often formed by an evaporation method and a film of a high molecular material is often formed by an ink-jet method or the like.

An evaporation apparatus which is used in an evaporation method has a substrate holder to which a substrate is mounted; a crucible (or an evaporation boat) containing an EL material, that is, an evaporation material; a heater for heating the EL material in the crucible; and a shutter for preventing the EL material from being scattered during sublimation. The EL material which is heated by the heater is sublimed and deposited onto the substrate.

Note that in order to achieve uniform deposition, actually, a deposition target substrate needs to be rotated and the substrate and the crucible need to be separated from each other by at least a certain distance. In addition, when films of different colors are separately formed using a plurality of EL materials through a mask such as a metal mask, it is necessary that the distance between pixels be designed to be large and that the width of a partition formed from an insulator provided between the pixels be large. Such demands are major objects in promoting improvement in definition (increase in the number of pixels) of a light-emitting device including a light-emitting element and miniaturization of display pixel pitches along with reduction in size of the light-emitting device including a light-emitting element.

Therefore, as for flat panel displays, it has been necessary to solve those problems as well as to achieve high productivity and cost reduction in order to achieve higher definition and higher reliability.

On the other hand, a technique is developed. In that technique, an organic material is uniformly deposited on a substrate that is referred to as a donor, and the donor on which the organic material is deposited is placed over/under an another substrate and irradiated with a laser beam, and an organic thin film (an EL layer of a light-emitting element) in a region irradiated with the laser beam is transferred to the another substrate (see References 1 to 5). As such a technique of laser transfer, laser-induced pattern-wise sublimation (LIPS), laser-induced thermal imaging (LITI) (see Reference 6), and radiation induced sublimation transfer (RIST) are proposed.

### REFERENCES

Reference 1: Japanese Translation of PCT International Application No. 2007-504621
Reference 2: Japanese Published Patent Application No. 2003-223991
Reference 3: Japanese Published Patent Application No. 2003-308974
Reference 4: Japanese Published Patent Application No. 2003-197372
Reference 5: Japanese Published Patent Application No. H10-208881
Reference 6: Japanese Published Patent Application No. 2006-5328

### SUMMARY OF THE INVENTION

As a method of laser transfer technique, a method is examined by which a donor (also referred to as a “donor substrate”) and a transfer receiving substrate (also referred to as a “deposition target substrate”) are moved closer to each other, and a region where a film is desired to be transferred is sealed under a reduced pressure, and the region is irradiated with a laser beam, whereby an organic thin film such as an EL layer is transferred to the transfer receiving substrate.

However, an organic thin film is deposited without laser transfer in a reduced-pressure state, for example, in an atmosphere having a pressure of less than or equal to 1×10⁻³ Pa. On the other hand, since sealing under a reduced pressure is performed in an atmosphere having a pressure of about 1 Pa, a contaminant might enter the organic thin film if laser transfer is performed in such an atmosphere. The entry of a contaminant into the organic thin film greatly affects luminescence properties.

Therefore, in order to obtain desired luminescence properties, it is necessary to maintain a reduced-pressure state in the space between a donor substrate and a transfer receiving substrate, for example, having a pressure of less than or equal to 1×10⁻³ Pa.

Thus, in order to perform laser transfer by laser beam irradiation while maintaining the space between the donor substrate and the transfer receiving substrate having a pressure of less than or equal to 1×10⁻³ Pa, the donor substrate and the transfer receiving substrate have been placed in a vacuum chamber provided with a light-transmitting window formed using quartz or the like and laser beam irradiation has been performed from the outside through the light-transmitting window.

However, when laser beam irradiation is performed through the light-transmitting window and the donor substrate, interference of the laser beam occurs due to complex multiple reflection on the light-transmitting window or the donor substrate. Therefore, uniform processing by the laser beam is difficult.

That is, when part of the laser beam is reflected at the interface between the light-transmitting window and an atmosphere and the reflected laser beam is emitted into the atmosphere again, a wider area than a region that should be irradiated is irradiated, and the region that should be irradiated and a region other than the region that should be irradiated are heated. In addition, energy efficiency is low because energy of the laser beam is lost due to reflection. Further, also when part of the laser beam is reflected at the interface between the donor substrate and a stacked film including a material layer, a similar phenomenon occurs.

The case where part of a laser beam is reflected at the interface between a light-transmitting window and an atmosphere is described with reference to FIG. 2. In FIG. 2, a laser beam 104 reaches a light absorption layer 105 formed on a donor substrate 102 through a light-transmitting window 141 and the donor substrate 102. Then, a material layer 106 formed on the light absorption layer 105 is transferred to a substrate 101.

However, in the structure illustrated in FIG. 2, the laser beam 104 has to pass through four interfaces before the laser beam 104 reaches the light absorption layer 105; the four interfaces are in the following order from the top: an interface between an atmosphere and the light-transmitting window 141, an interface between the light-transmitting window 141 and an atmosphere, an interface between the atmosphere and the donor substrate 102, and an interface between the donor substrate 102 and the light absorption layer 105. Therefore, complex multiple reflection occurs, and interference is generated. As a result, energy distribution varies due to the interference. Note that in FIG. 2, reflected light 144 that is reflected at the interface between the light-transmitting window 141 and the atmosphere, emission light 145 that has passed through the light-transmitting window 141, and reflected light 146 that is reflected at the interface between the donor substrate 102 and the light absorption layer 105 are illustrated.

It is preferable that the light absorption layer 105 be irradiated with only the laser beam 104; however, when reflection occurs inside the light-transmitting window 141, interference of the reflected light 144 and the laser beam 104 occurs, and the energy distribution varies.

That is, because of the change of the energy distribution, the material layer 106 might be transferred unevenly to have an uneven thickness.

In particular, multiple reflection in the donor substrate 102 causes higher interference when the donor substrate 102 has a small thickness of less than or equal to 1 mm.

In addition, high energy density is necessary for a laser beam in order to heat a region having a small area at a shot. Therefore, it is preferable that the distance between an optical system and a treatment substrate be shortened as much as possible. The distance between a surface of a transfer receiving substrate and a lens needs to be less than or equal to several centimeters depending on a design. When the distance among the transfer receiving substrate, the light-transmitting window, and the optical system is short as in the above case, an apparatus should have a complicated structure, which makes it difficult to perform maintenance and to replicate treatment.

Thus, it is an object to provide a technique that enables transfer by laser irradiation without unevenness while a high degree of vacuum is maintained in the space between the donor substrate and the transfer receiving substrate.

In one embodiment of the present invention, a donor substrate on which a light absorption layer and a material layer are stacked is used as a light-transmitting window of a vacuum jig, whereby a high degree of vacuum is maintained in the space between the donor substrate and a transfer receiving substrate, and laser irradiation is performed without unevenness.

In one embodiment of the present invention, a donor substrate on which a light absorption layer and a material layer are stacked is provided as a light-transmitting window of a vacuum jig, and a transfer receiving substrate is provided close to the donor substrate. The degree of vacuum of the atmosphere in the vacuum jig is, for example, less than or equal to 10⁻³ Pa by using a vacuum pump or the like, and laser beam irradiation is performed from a surface of the donor substrate (referred to as a “back surface” or a “second surface” in this specification) that is opposite to a surface facing the transfer receiving substrate, namely, a surface (referred to as a “surface” or a “first surface” in this specification) on which the light absorption layer and the material layer are stacked. Thus, a material layer with extremely small number of impurities is transferred to the transfer receiving substrate, namely, an EL material of the material layer is sublimated or comes off, and deposited on the transfer receiving substrate.

In this case, it is preferable that the donor substrate, which is a light-transmitting window, have a thickness of greater than or equal to 1 cm so as to be able to withstand vacuum pressure. A thick donor substrate has an advantage of suppressing interference.

For a laser beam, a continuous wave laser (also referred to as a CW laser) is used. Alternatively, a mode-locked laser having a repetition rate of as high as 10 MHz may be used. A laser having a short pulse width is preferably used because interference due to light that is reflected on the surface of the donor substrate and is returned to the light absorption layer can be suppressed. For example, when a laser of about 30 ps is used, interference can be suppressed if the donor substrate has a thickness of greater than or equal to 5 mm. Instead of a laser beam, different light of a flash lamp or the like may be used.

One embodiment of the present invention relates to a film deposition method in which a first substrate has a light-transmitting property and has a first surface provided with a light absorption layer and a material layer having a light-emitting material, is made to face a second substrate; the second substrate facing the first substrate is placed in an inner space of a vacuum jig; pressure in the inner space of the vacuum jig is reduced; and light is emitted to a second surface which is a surface on a side opposite to the first surface of the first substrate, and the material layer in a region irradiated with the light is moved and film deposition is performed over the second substrate.

One embodiment of the present invention relates to a film deposition method in which a light absorption layer and a material layer having a light-emitting material are formed over a first surface of a first substrate having a light-transmitting property; the first surface of the first substrate over which the material layer is deposited is made to face a second substrate; the second substrate facing the first substrate is placed in an inner space of a vacuum jig; pressure in the inner space of the vacuum jig is reduced; and light is emitted to a second surface which is a surface on a side opposite to the first surface of the first substrate, and the material layer in a region irradiated with the light is moved and film deposition is performed over the second substrate.

One embodiment of the present invention relates to a method for manufacturing a light-emitting element, in which a light absorption layer and a material layer having a light-emitting material are formed over a first surface of a first substrate having a light-transmitting property; a first electrode is formed over a second substrate; the first surface of the first substrate over which the material layer is deposited is made to face a surface of the second substrate over which the first electrode is formed; the second substrate facing the first substrate is placed in an inner space of a vacuum jig; pressure in the inner space of the vacuum jig is reduced; light is emitted to a second surface which is a surface on a side opposite to the first surface of the first substrate, and the material layer in a region irradiated with the light is moved and film deposition is performed over the first electrode of the second substrate; and a second electrode is formed over the material layer.

One embodiment of the present invention relates to a method for manufacturing a light-emitting element, in which a light absorption layer, a second electrode, and a material layer having a light-emitting material are formed over a first surface of a first substrate having a light-transmitting property; a first electrode is formed over a second substrate; the first surface of the first substrate over which the second electrode and the material layer are deposited is made to face a surface of the second substrate over which the first electrode is formed; the second substrate facing the first substrate is placed in an inner space of a vacuum jig; pressure in the inner space of the vacuum jig is reduced; and light is emitted to a second surface which is a surface on a side opposite to the first surface of the first substrate, and the material layer in a region irradiated with the light is moved, and the material layer and the second electrode are formed over the first electrode of the second substrate.

One embodiment of the present invention relates to a method for manufacturing a light-emitting element, in which a light absorption layer, a first electrode, and a material layer having a light-emitting material are formed over a first surface of a first substrate having a light-transmitting property; the first surface of the first substrate over which the first electrode and the material layer are formed is made to face a second substrate; the second substrate facing the first substrate is placed in an inner space of a vacuum jig; pressure in the inner space of the vacuum jig is reduced; light is emitted to a second surface which is a surface on a side opposite to the first surface of the first substrate, and the material layer in a region irradiated with the light is moved, and the first electrode and the material layer are formed over the second substrate; and a second electrode is formed over the material layer.

One embodiment of the present invention relates to a method for manufacturing a light-emitting element, in which a light absorption layer, a first electrode, a material layer having a light-emitting material, and a second electrode are formed over a first surface of a first substrate having a light-transmitting property; the first surface of the first substrate over which the first electrode, the material layer, and the second electrode are formed is made to face a second substrate; the second substrate facing the first substrate is placed in an inner space of a vacuum jig; pressure in the inner space of the vacuum jig is reduced; light is emitted to a second surface which is a surface on a side opposite to the first surface of the first substrate, and the material layer in a region irradiated with the light is moved, and the first electrode, the material layer, and the second electrode are formed over the second substrate.

A support member for further decreasing a distance between the first substrate and the second substrate is provided between a lower part of the vacuum jig and the second substrate.

The support member includes a spring and a protective member.

The donor substrate on which the light absorption layer and the material layer are stacked is used as the light-transmitting window of the vacuum jig, whereby a high degree of vacuum can be maintained in the space between the donor substrate and the transfer receiving substrate.

Therefore, in performing transfer by laser irradiation, a contaminant can be prevented from entering the material layer, and high organic EL luminescence properties can be obtained.

In addition, the donor substrate is used as the light-transmitting window of the vacuum jig, whereby interference due to complex multiple reflection can be prevented and uniform laser irradiation treatment can be performed.

### BRIEF DESCRIPTION OF THE DRAWINGS

FIGS. 1A to 1E illustrate a method for film deposition.

FIG. 2 illustrates reflection and interference of a laser beam.

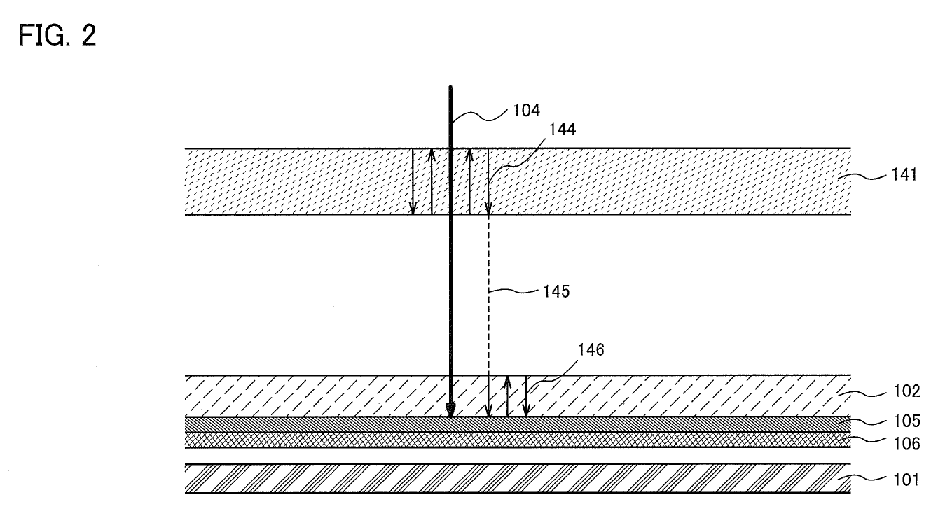

FIG. 3 illustrates a light-emitting element.

FIG. 4 illustrates a light-emitting element.

FIGS. 5A to 5C illustrate a passive-matrix light-emitting device.

FIG. 6 illustrates a passive-matrix light-emitting device.

FIGS. 7A and 7B illustrate an active-matrix light-emitting device.

FIGS. 8A to 8E illustrate electronic devices.

FIGS. 9A to 9C illustrate an electronic device.

FIGS. 10A to 10E illustrate a method for manufacturing a light-emitting element.

FIGS. 11A to 11E illustrate a method for manufacturing a light-emitting element.

FIGS. 12A to 12E illustrate a method for manufacturing a light-emitting element.

FIGS. 13A to 13E illustrate a method for manufacturing a light-emitting element.

FIGS. 14A and 14B illustrate a method for manufacturing a light-emitting element.

FIGS. 15A to 15C illustrate a positional relationship between a transfer receiving substrate and a support member.

### DETAILED DESCRIPTION OF THE INVENTION

### Embodiments

Embodiments of the present invention disclosed in this specification will be described hereinafter with reference to the accompanying drawings. However, it is easily understood by those skilled in the art that the present invention disclosed in this specification can be carried out in many different modes, and the mode and detail of the present invention disclosed in this specification can be variously changed without departing from the spirit and scope thereof. Therefore, the present invention disclosed in this specification should not be construed as being limited to description of the embodiments. Note that identical portions or portions having the same functions in the drawings are denoted by the same reference numerals and detailed descriptions thereof are omitted.

### Embodiment 1

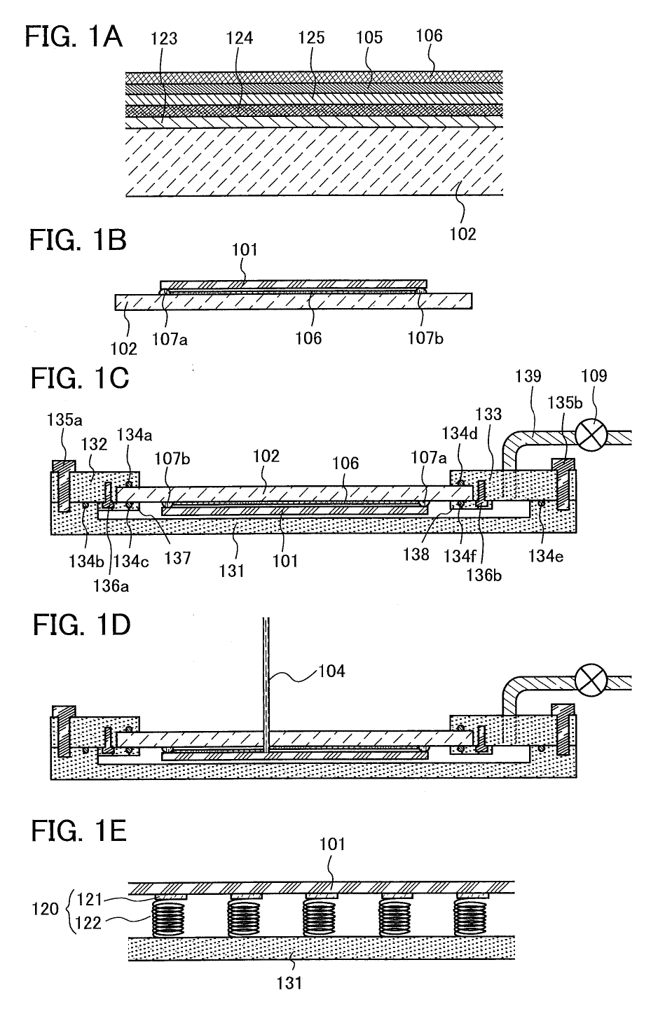

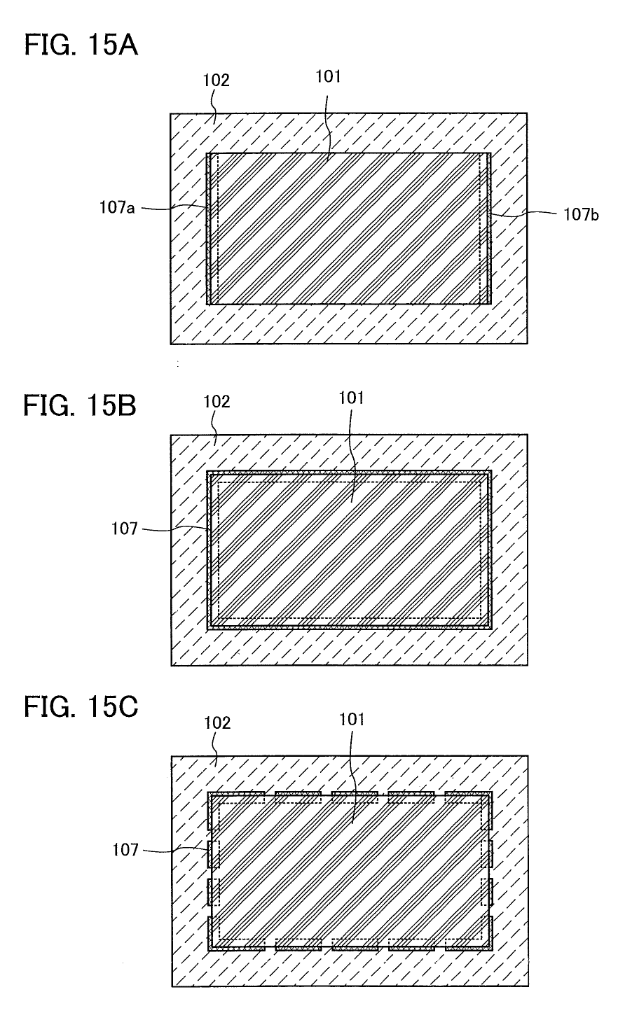

This embodiment will be described with reference to FIGS. 1A to 1E and FIGS. 15A to 15C.

First, a base film 123, a reflective layer 124, a heat insulating layer 125, the light absorption layer 105, and the material layer 106 are formed over the donor substrate (also referred to as the “first substrate”) 102 (see FIG. 1A).

The donor substrate 102 is made using any material (e.g., quartz or glass) as long as it has a light-transmitting property. In this embodiment, a glass substrate is used as the donor substrate 102. In addition, since the donor substrate 102 is used as a light-transmitting window of a vacuum jig, it is preferable that the donor substrate 102 have a thickness of greater than or equal to 1 cm and be strong.

The base film 123 can be formed using a single film or a plurality of stacked films selected from a silicon oxide film, a silicon oxide film containing nitrogen, or a silicon nitride film containing oxygen. In this embodiment, a silicon oxide film containing nitrogen is used as the base film 123.

In order that part of the light absorption layer 105 is selectively irradiated with light (a laser beam) at the time of transfer by laser irradiation, the reflective layer 124 serves as a layer for reflecting light emitted to the light absorption layer 105 other than the part of the light absorption layer 105. Therefore, the reflective layer 124 is preferably formed from a material having high reflectance for the irradiation light. Specifically, the reflective layer 124 preferably has a reflectance of greater than or equal to 85%, more preferably, a reflectance of greater than or equal to 90% with respect to the irradiation light.

As a material for the reflective layer 124, for example, silver, gold, platinum, copper, an alloy containing aluminum, an alloy containing silver, a stacked film in which indium tin oxide is stacked over any of these materials, or the like can be used.

Note that since a kind of material that is suitable for the reflective layer 124 varies depending on the wavelength of the irradiation light, the material of the reflective layer 124 needs to be selected as appropriate.

Note that the reflective layer 124 can be formed by any of a variety of methods. For example, the reflective layer 124 can be formed by a sputtering method, an electron beam evaporation method, a vacuum evaporation method, or the like. It is preferable that the thickness of the reflective layer 124 be greater than or equal to 100 nm although it depends on a material. With a thickness of greater than or equal to 100 nm, transmission of the irradiation light through the reflective layer can be suppressed.

In this embodiment, aluminum is used for the reflective layer 124.

The heat insulating layer 125 is a layer for preventing heat from being conducted to the light absorption layer 105 and the material layer 106, which are formed in later steps, if the irradiation light (the laser beam) in laser transfer which is reflected by the reflective layer 124 partially remains as heat in the reflective layer. Accordingly, the heat insulating layer 125 needs to be formed using a material having a lower thermal conductivity than materials forming the reflective layer 124 and the light absorption layer 105.

A material for the heat insulating layer 125 can be, for example, titanium oxide, silicon oxide, silicon nitride oxide, zirconium oxide, or silicon carbide.

Note that the heat insulating layer 125 can be formed by any of a variety of methods. For example, the heat insulating layer 125 can be formed by a sputtering method, an electron beam evaporation method, a vacuum evaporation method, a CVD method, or the like. In addition, the thickness of the heat insulating layer 125 is preferably greater than or equal to 10 nm and less than or equal to 2 μm, more preferably, greater than or equal to 100 nm and less than or equal to 600 nm although it depends on a material.

In this embodiment, silicon oxide is used for the heat insulating layer 125.

The light absorption layer 105 can be formed by any of a variety of materials. For example, metal nitride such as titanium nitride, tantalum nitride, molybdenum nitride, or tungsten nitride; metal such as titanium, molybdenum, or tungsten; carbon; or the like can be used. Note that since a kind of material that is suitable for the light absorption layer 105 varies depending on the wavelength of the irradiation light, the material of the light absorption layer 105 needs to be selected as appropriate. For example, for light having a wavelength of 800 nm, molybdenum, tantalum nitride, titanium, tungsten, or the like is preferably used.

For light having a wavelength of 1300 nm, tantalum nitride, titanium, or the like is preferably used. In addition, the light absorption layer 105 is not limited to a single layer and may include a plurality of layers. For example, the light absorption layer 105 may have a stacked structure of metal and metal nitride.

Note that the light absorption layer 105 can be formed by any of a variety of methods. For example, the light absorption layer 105 can be formed by a sputtering method, an electron beam evaporation method, a vacuum evaporation method, or the like.

It is preferable that the light absorption layer 105 have a thickness with which the irradiation light is not transmitted although it depends on a material. Specifically, it is preferable that the light absorption layer 105 have a thickness of greater than or equal to 10 nm and less than or equal to 2 μm. In addition, since the light absorption layer 105 with a small thickness can be formed by a laser beam with lower energy, it is preferable that the light absorption layer 105 have a thickness of greater than or equal to 10 nm and less than or equal to 600 nm. On the other hand, if the light absorption layer is too thin, the amount of transmitted light increases; therefore, the light absorption layer 105 needs to have a thickness of greater than or equal to 10 nm at least. For example, when irradiation with light having a wavelength of 532 nm is performed, the light absorption layer 105 can have a thickness of greater than or equal to 50 nm and less than or equal to 200 nm, whereby irradiation light can be efficiently absorbed and heat can be generated.

Note that the light absorption layer 105 may transmit part of irradiation light if a material included in the material layer 106 can be heated to a temperature at which film deposition of the material included in the material layer 106 can be performed (temperature at which at least part of the material included in the material layer is deposited on a deposition target substrate). Note that when the light absorption layer 105 transmits part of the irradiation light, it is necessary to use a material that is not decomposed by light as the material included in the material layer 106.

Furthermore, the greater the difference in reflectance between the reflective layer 124 and the light absorption layer 105 is, the more preferable it is. Specifically, the difference in reflectance for the wavelength of the irradiation light is preferably greater than or equal to 25%, more preferably, greater than or equal to 30%.

In this embodiment, the light absorption layer 105 is formed using titanium.

When the material layer 106 is heated, at least part of the material included in the material layer 106 is vaporized (sublimated), or when thermal deformation occurs in at least part of the material layer 106, and as a result, a film comes off due to a change of stress, so that transfer is performed to the transfer receiving substrate (also referred to as the “second substrate”) 101. That is, the material layer 106 formed over the donor substrate 102 is moved due to light irradiation and deposited on the transfer receiving substrate 101.

As the transfer receiving substrate 101, a substrate with an insulating surface or an insulating substrate is used. Specifically, any of a variety of glass substrates used for the electronics industry, such as aluminosilicate glass, aluminoborosilicate glass, or barium borosilicate glass; a quartz substrate; a ceramic substrate; a sapphire substrate; or the like can be used.

Note that any material can be used as the material included in the material layer 106 regardless of whether it is an organic compound or an inorganic compound as long as the material can be deposited.

As described in this embodiment, when an EL layer of a light-emitting element is formed as the material layer 106, a material which can be deposited to form the EL layer is used. For the material layer 106, an organic compound such as a light-emitting material or a carrier-transporting material, a carrier-transporting layer, or a carrier-injecting layer can be used. If it is possible, an inorganic compound which is used for an electrode or the like of a light-emitting element, such as metal oxide, metal nitride, metal halide, or an elementary metal, other than an organic material, can be used.

The material layer 106 may contain a plurality of materials. The material layer 106 may be a single layer or a plurality of stacked layers. Accordingly, by stacking a plurality of layers each containing a material, co-evaporation is possible.

The material layer 106 is formed by any of a variety of methods. For example, a wet method such as a spin coating method, a spray coating method, an ink-jet method, a dip coating method, a casting method, a die coating method, a roll coating method, a blade coating method, a bar coating method, a gravure coating method, or a printing method can be used. Alternatively, a dry method such as a vacuum evaporation method or a sputtering method can be used.

In the case of forming the material layer 106 by a wet method, a desired material may be dissolved or dispersed in a solvent, and a solution or a dispersion solution may be adjusted. There is no particular limitation on the solvent as long as a material can be dissolved or dispersed therein and the solvent does not react with the material. For example, as a solvent, any of the following can be used: halogen-based solvents such as chloroform, tetrachloromethane, dichloromethane, 1,2-dichloroethane, and chlorobenzene; ketone-based solvents such as acetone, methyl ethyl ketone, diethyl ketone, n-propyl methyl ketone, and cyclohexanone; aromatic-based solvents such as benzene, toluene, and xylene; ester-based solvents such as ethyl acetate, n-propyl acetate, n-butyl acetate, ethyl propionate, γ-butyrolactone, and diethyl carbonate; ether-based solvents such as tetrahydrofuran and dioxane; amide-based solvents such as dimethylformamide and dimethylacetamide; dimethyl sulfoxide; hexane; water; and the like. A mixture of plural kinds of these solvents may also be used. By using a wet method, it is possible to increase material use efficiency, which leads to a reduction in manufacturing cost.

Note that in the case where the thickness and uniformity of a film which is formed over the deposition target substrate with the material layer 106 are controlled, the thickness and uniformity of the material layer 106 need to be controlled. However, the material layer 106 does not need to be a uniform layer if the thickness and uniformity of a layer which is formed over the donor substrate 102 is not affected. For example, the material layer 106 may be formed in a minute island shape or may be formed in an uneven layer shape.

After the base film 123, the reflective layer 124, the heat insulating layer 125, the light absorption layer 105, and the material layer 106 are formed over the donor substrate 102, the surface of the donor substrate 102 where deposition is performed is made to face the transfer receiving substrate 101. At this time, the donor substrate 102 and the transfer receiving substrate 101 are supported by a support member 107 (a support member 107a and a support member 107b) so that the distance between the donor substrate 102 and the transfer receiving substrate 101 is about 1 μm (see FIG. 1B).

The support member 107 maintains the distance between the donor substrate 102 and the transfer receiving substrate 101. FIGS. 15A to 15C are top views each illustrating a positional relationship among the donor substrate 102, the transfer receiving substrate 101, and the support member 107. The support member 107 may be formed along two sides which face each other and are located at end portions of the transfer receiving substrate 101 (see FIG. 15A); the support member 107 may surround all the end portions of the transfer receiving substrate 101 (see FIG. 15B); or the support member 107 may surround end portions of the transfer receiving substrate 101 and have a gap (see FIG. 15C).

The donor substrate 102 and the transfer receiving substrate 101 are placed in a vacuum jig, and when the inside of the vacuum jig is depressurized, the space between the donor substrate 102 and the transfer receiving substrate 101 is also depressurized. Therefore, even when the support member 107 surrounds all the end portions of the transfer receiving substrate 101 as seen in FIG. 15B, the support member 107 is placed so that the space between the donor substrate 102 and the transfer receiving substrate 101 can be depressurized.

The support member 107 is not necessarily provided, and in that case, the donor substrate 102 and the transfer receiving substrate 101 are disposed in close contact with each other. In addition, either when the support member 107 is provided or when the support member 107 is not provided, the transfer receiving substrate 101 may be supported by a support member 120 which has a spring 122 and a protective member 121 to be described later.

A vacuum jig illustrated in FIG. 1C includes a lower part 131, an upper part 132, an upper part 133, a jig 137 and a jig 138 which hold the donor substrate 102, a screw 135a which fixes the upper part 132 and the lower part 131, a screw 135b which fixes the upper part 133 and the lower part 131, a screw 136a which fixes the upper part 132 and the jig 137, a screw 136b which fixes the upper part 133 and the jig 138, an O-ring 134a which prevents vacuum leakage between the donor substrate 102 and the upper part 132, an O-ring 134b which prevents vacuum leakage between the upper part 132 and the lower part 131, an O-ring 134c which prevents vacuum leakage between the donor substrate 102 and the jig 137, an O-ring 134d which prevents vacuum leakage between the donor substrate 102 and the upper part 133, an O-ring 134e which prevents vacuum leakage between the upper part 133 and the lower part 131, an O-ring 134f which prevents vacuum leakage between the donor substrate 102 and the jig 138, a pipe 139 which connects an inner space of the vacuum jig to a vacuum pump, and a valve 109 provided for the pipe.

The inner space of the vacuum jig is placed in a reduced-pressure state that can be seen as a vacuum state, or low pressure that is close to the reduced-pressure state, for example, 10⁻³ Pa, by using the vacuum pump.

Of the two substrates which are bonded, namely, the donor substrate 102 and the transfer receiving substrate 101, at least the transfer receiving substrate 101 is placed in the inner space of the vacuum jig. That is, the donor substrate 102 functions as an irradiation window of the vacuum jig, and the transfer receiving substrate 101 is provided in the inner space of the vacuum jig to face the donor substrate 102.

Then, the inner space of the vacuum jig in which the transfer receiving substrate 101 is placed becomes in a reduced-pressure state that can be seen as a vacuum state or a low pressure that is close to the reduced-pressure state, for example, a pressure of 10⁻³ Pa, by using the vacuum pump. Thus, the space between the donor substrate 102 and the transfer receiving substrate 101 is also depressurized.

Next, the laser beam 104 is emitted to a surface (a back surface) of the donor substrate 102 where the light absorption layer 105 and the material layer 106 are not formed, whereby the material layer 106 in a region of the donor substrate 102 which is irradiated with the laser beam 104 is sublimated and formed on the transfer receiving substrate 101 (see FIG. 1D).

Note that for the laser beam 104 which can be used in this embodiment, a gas laser or a solid state laser can be used. Examples of the gas laser include an Ar laser, a Kr laser, an excimer laser, a copper vapor laser, a gold vapor laser, and the like. Examples of the solid state laser include a laser, of which a medium is single crystal YAG, YVO₄, forsterite (Mg₂SiO₄), YAlO₃, or GdVO₄, or polycrystalline (ceramic) YAG, Y₂O₃, YVO₄, YAlO₃, or GdVO₄ doped with one or more of Nd, Yb, Cr, Ti, Ho, Er, Tm, and Ta as a dopant; a glass laser; a ruby laser; an alexandrite laser; a Ti:sapphire laser; and the like. A laser beam oscillated from one or more of the above lasers can be selected to be used.

A laser beam of second to fourth harmonics of such a solid state laser can be used. For example, a second harmonic (532 nm) or a third harmonic (355 nm) of an Nd:YVO₄ laser (with a fundamental wave of 1064 nm) can be used. In this case, the power density of about 0.01 MW/cm² to 100 MW/cm² (preferably, 0.1 MW/cm² to 10 MW/cm²) is required for a laser. When a continuous wave laser is used, a laser beam is applied at a scanning rate of about 10 cm/sec to 2000 cm/sec.

Note that a laser using, as a medium, single crystal YAG, YVO₄, forsterite (Mg₂SiO₄), YAlO₃, or GdVO₄ or polycrystalline (ceramic) YAG, Y₂O₃, YVO₄, YAlO₃, or GdVO₄ doped with one or more of Nd, Yb, Cr, Ti, Ho, Er, Tm, and Ta as a dopant; an Ar ion laser; or a Ti: sapphire laser can be continuously oscillated. Further, also when pulse oscillation is performed with a repetition rate of greater than or equal to 10 MHz by performing a Q switch operation or mode locking of these lasers, an effect similar to that of a continuous wave laser can be obtained.

By placing the vacuum jig on a stage which is scanned in the X direction and the Y direction, whereby the entire surface of the donor substrate 102 can be irradiated with the laser beam 104.

Although the case in which a laser beam is used as the light is described, different light of a flash lamp or the like may be used.

As illustrated in FIG. 1E, the support member 120 that maintains the distance between the transfer receiving substrate 101 and the donor substrate 102 may be provided between the lower part 131 of the vacuum jig and the transfer receiving substrate 101. In this embodiment, the spring 122 and the protective member 121 are provided as the support member 120. The spring 122 has a function of further decreasing the distance between the transfer receiving substrate 101 and the donor substrate 102. The protective member 121 is provided between the spring 122 and the transfer receiving substrate 101, and protects the transfer receiving substrate 101. A metal spring may be used as the spring 122, and an organic resin or an inorganic resin may be used as the protective member 121.

In this embodiment, the donor substrate 102 over which the light absorption layer 105 and the material layer 106 are stacked is used as the light-transmitting window of the vacuum jig, whereby a high degree of vacuum can be maintained in the space between the donor substrate 102 and the transfer receiving substrate 101.

Therefore, in performing transfer by laser irradiation to be described later, a contaminant can be prevented from entering the material layer 106.

In addition, even if complex multiple reflection of the laser beam 104 occurs, interference due to the complex multiple reflection can be prevented and uniform laser irradiation treatment can be performed by using the donor substrate 102 as the light-transmitting window of the vacuum jig.

### Embodiment 2

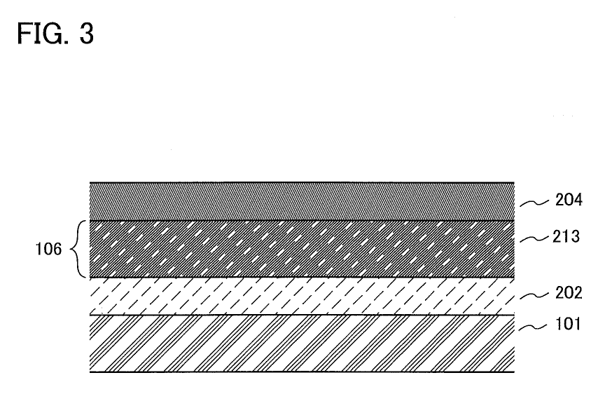

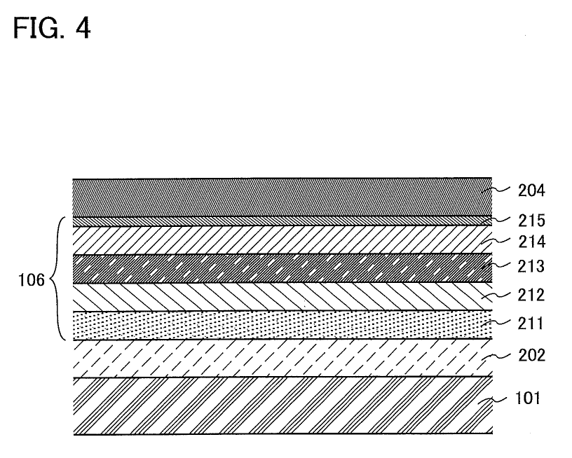

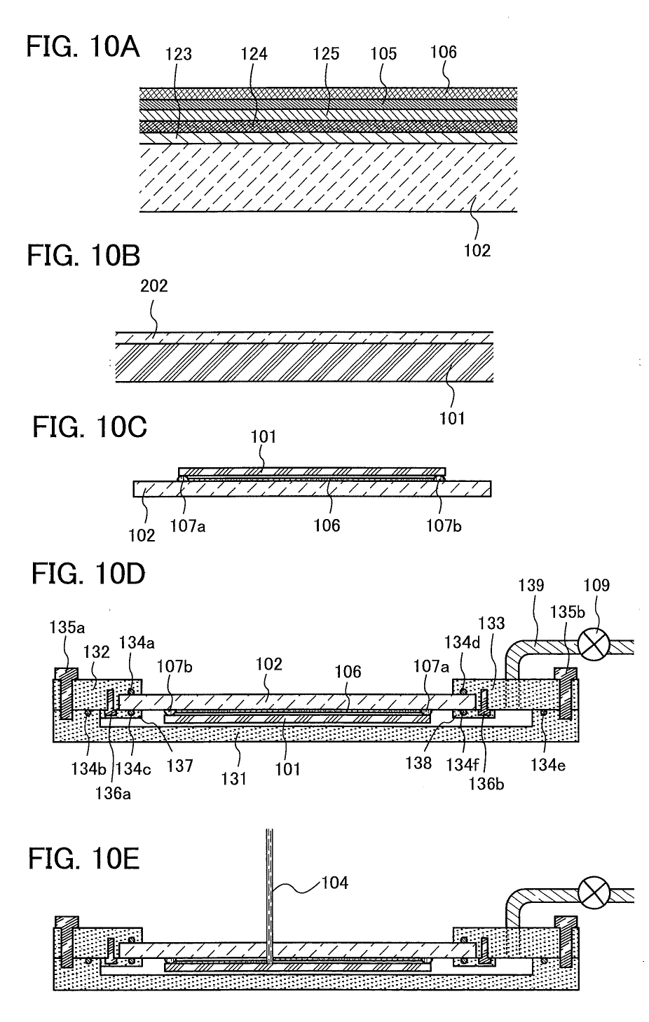

In this embodiment, a method for manufacturing a light-emitting element will be described with reference to FIG. 3, FIG. 4, FIGS. 10A to 10E, FIGS. 11A to 11E, FIGS. 12A to 12E, FIGS. 13A to 13E, and FIGS. 14A and 14B.

In a light-emitting element illustrated in FIG. 3, a first electrode 202, the material layer (also referred to as the EL layer) 106 which includes only a light-emitting layer 213, and a second electrode 204 are sequentially stacked over the substrate 101.

One of the first electrode 202 and the second electrode 204 functions as an anode, and the other functions as a cathode. Holes injected from the anode and electrons injected from the cathode are recombined in the material layer 106, whereby light emission can be obtained.

In this embodiment, the first electrode 202 functions as the anode and the second electrode 204 functions as the cathode.

In a light-emitting element illustrated in FIG. 4, the material layer 106 in FIG. 3 has a stacked structure including a plurality of layers. Specifically, a hole-injecting layer 211, a hole-transporting layer 212, the light-emitting layer 213, an electron-transporting layer 214, and an electron-injecting layer 215 are sequentially provided from the first electrode 202 side.

Note that the material layer 106 is not necessarily provided with all of these layers, and the layers may be selected as appropriate and provided.

For the first electrode 202 and the second electrode 204, various kinds of metals, alloys, electrically conductive compounds, mixtures thereof, and the like can be used. Specifically, for example, indium tin oxide (ITO), indium tin oxide containing silicon or silicon oxide, indium zinc oxide (IZO), and indium oxide containing tungsten oxide and zinc oxide. In addition, gold (Au), platinum (Pt), nickel (Ni), tungsten (W), chromium (Cr), molybdenum (Mo), iron (Fe), cobalt (Co), copper (Cu), palladium (Pd), nitride of a metal material (such as titanium nitride), and the like can be given.

These materials are usually formed by a sputtering method. For example, indium zinc oxide can be formed by a sputtering method using a target in which zinc oxide is added to indium oxide at 1 wt % to 20 wt %. Indium oxide containing tungsten oxide and zinc oxide can be formed by a sputtering method using a target in which tungsten oxide and zinc oxide are added to indium oxide at 0.5 wt % to 5 wt % and 0.1 wt % to 1 wt %, respectively. Alternatively, by application of a sol-gel method or the like, an ink-jet method, a spin coating method, or the like may be used for the formation.

Furthermore, aluminum (Al), silver (Ag), an alloy containing aluminum, or the like can be used. Moreover, any of the following materials having a low work function can be used: elements which belong to Group 1 and Group 2 of the periodic table, that is, alkali metals such as lithium (Li) and cesium (Cs) and alkaline earth metals such as magnesium (Mg), calcium (Ca), and strontium (Sr), and alloys thereof (an alloy of aluminum, magnesium, and silver, and an alloy of aluminum and lithium); rare earth metals such as europium (Eu) and ytterbium (Yb), and alloys thereof; and the like.

A film of an alkali metal, an alkaline earth metal, or an alloy including these can be formed by a vacuum evaporation method. In addition, an alloy including an alkali metal or an alkaline earth metal can be formed by a sputtering method. Further, silver paste or the like can be formed by an ink-jet method or the like. The first electrode 202 and the second electrode 204 each are not limited to a single-layer film and may be a stacked film.

Note that in order to extract light emitted in the material layer 106 to the outside, one or both of the first electrode 202 and the second electrode 204 are formed so as to transmit light. For example, one or both of the first electrode 202 and the second electrode 204 is/are formed using a conductive material having a light-transmitting property, such as indium tin oxide, or formed using silver, aluminum, or the like to a thickness of several nanometers to several tens of nanometers. Alternatively, one or both of the first electrode 202 and the second electrode 204 can have a stacked structure including a thin film of a metal such as silver or aluminum and a thin film of a conductive material having a light-transmitting property, such as ITO.

One or both of the first electrode 202 and the second electrode 204 can be formed by the film deposition method described in Embodiment 1.

For example, when a light-emitting element that has the material layer 106 in which only the light-emitting layer 213 is provided is formed as illustrated in FIG. 3, the light-emitting layer 213 is formed as the material layer 106 which is over the donor substrate 102 described in Embodiment 1 (see FIG. 10A), and the first electrode 202 is formed over the substrate 101 (see FIG. 10B). The surface of the donor substrate 102 where the material layer 106 is formed is made to face a surface of the substrate 101 where the first electrode 202 is formed (see FIG. 10C), and the donor substrate 102 and the substrate 101 are placed in the vacuum jig (see FIG. 10D).

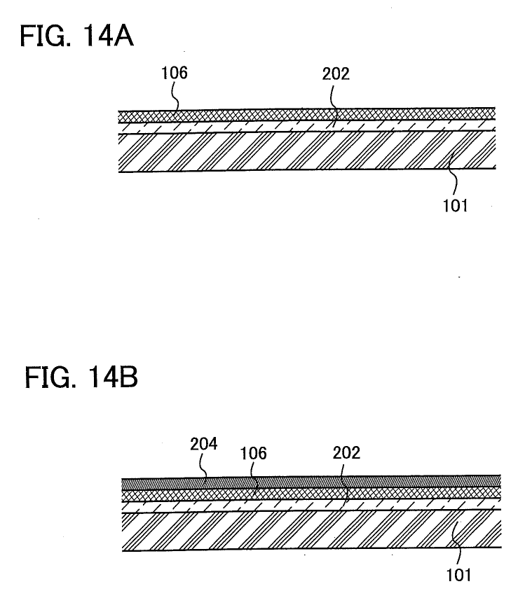

As described in Embodiment 1, the laser beam 104 is applied (see FIG. 10E), whereby the material layer 106 is formed over the first electrode 202 over the substrate 101 (see FIG. 14A).

Then, the donor substrate 102 and the substrate 101 are taken out from the vacuum jig, and the second electrode 204 is formed over the material layer 106, whereby a light-emitting element illustrated in FIG. 14B can be obtained. Note that in the structure illustrated in FIG. 3, the material layer 106 has only the light-emitting layer 213.

In order to form the first electrode 202 and the material layer 106 over the substrate 101 by laser transfer, a manufacturing process described hereinafter may be used.

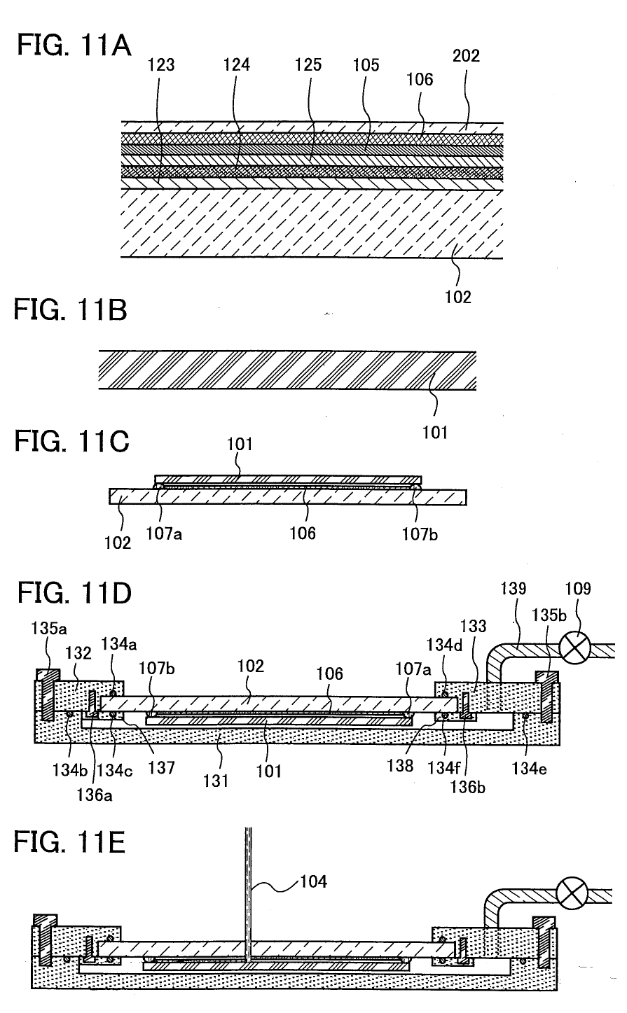

That is, the material layer 106 and the first electrode 202 are formed over the donor substrate 102 (see FIG. 11A), and the substrate 101 is prepared (see FIG. 11B). The surface of the donor substrate 102 where the material layer 106 is formed is made to face the substrate 101 (see FIG. 11C), and the donor substrate 102 and the substrate 101 are placed in the vacuum jig (see FIG. 11D).

As described in Embodiment 1, the laser beam 104 is applied (see FIG. 11E), whereby the first electrode 202 and the material layer 106 are formed over the substrate 101 (see FIG. 14A).

Then, the donor substrate 102 and the substrate 101 are taken out from the vacuum jig, and the second electrode 204 is formed over the material layer 106, whereby the light-emitting element illustrated in FIG. 14B can be obtained. Note that in the structure illustrated in FIG. 3, the material layer 106 has only the light-emitting layer 213.

In order to form the material layer 106 and the second electrode 204 over the substrate 101 by laser transfer, a manufacturing process described hereinafter may be used.

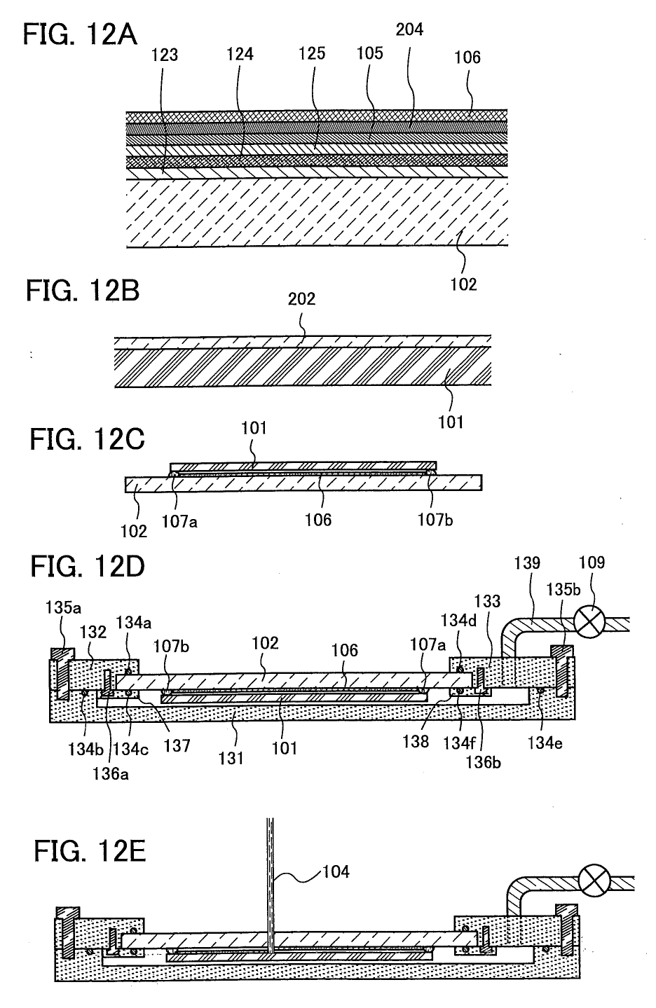

That is, the second electrode 204 and the material layer 106 are formed over the donor substrate 102 (see FIG. 12A), and the first electrode 202 is formed over the substrate 101 (see FIG. 12B). The surface of the donor substrate 102 where the material layer 106 is formed is made to face a surface of the substrate 101 where the first electrode 202 is formed (see FIG. 12C), and the donor substrate 102 and the substrate 101 are placed in the vacuum jig (see FIG. 12D).

As described in Embodiment 1, the laser beam 104 is applied (see FIG. 12E), whereby the material layer 106 and the second electrode 204 are formed over the first electrode 202 over the substrate 101 (see FIG. 14B). Thus, the light-emitting element illustrated in FIG. 14B can be obtained. Note that in the structure illustrated in FIG. 3, the material layer 106 has only the light-emitting layer 213.

In order to form the first electrode 202, the material layer 106, and the second electrode 204 over the substrate 101 by laser transfer, a manufacturing process described hereinafter may be used.

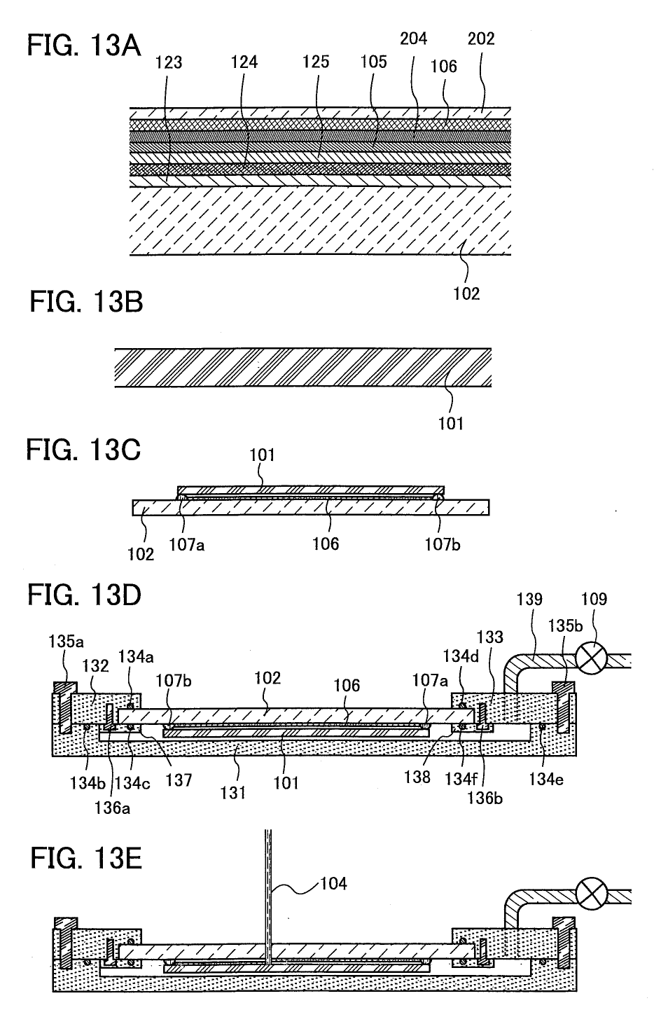

That is, the second electrode 204, the material layer 106, and the first electrode 202 are formed over the donor substrate 102 (see FIG. 13A), and the substrate 101 is prepared (see FIG. 13B). The surface of the donor substrate 102 where the first electrode 202 is formed is made to face the substrate 101 (see FIG. 13C), and the donor substrate 102 and the substrate 101 are placed in the vacuum jig (see FIG. 13D).

As described in Embodiment 1, the laser beam 104 is applied (see FIG. 13E), whereby the first electrode 202, the material layer 106, and the second electrode 204 are formed over the substrate 101 (see FIG. 14B). Thus, the light-emitting element illustrated in FIG. 14B can be obtained. Note that in the structure illustrated in FIG. 3, the material layer 106 has only the light-emitting layer 213.

Any of a variety of materials can be used for the light-emitting layer 213. For example, a fluorescent compound which exhibits fluorescence or a phosphorescent compound which exhibits phosphorescence can be used.

As the phosphorescent compound which can be used for the light-emitting layer 213, any of the materials below can be used. For example, as a blue-light-emitting material, the following can be given: bis[2-(4′,6′-difluorophenyl)pyridinato-N,C^{2′}]iridium(III)tetrakis(1-pyrazolyl)borate (abbreviation: FIr6); bis[2-(4′,6′-difluorophenyl)pyridinato-N,C^{2′}]iridium(III)picolinate (abbreviation: FIrpic); bis[2-(3′,5′-bistrifluoromethyl)pyridinato-N,C^{2′}]iridium(III)picolinate (abbreviation: Ir(CF₃ ppy)₂(pic)); bis[2-(4′,6′-difluorophenyl)pyridinato-N,C^{2′}]iridium(III)acetylacetonate (abbreviation: FIr(acac)); and the like. As a green-light-emitting material, the following can be given: tris(2-phenylpyridinato-N,C^{2′})iridium(III) (abbreviation: Ir(ppy)₃); bis(2-phenylpyridinato-N,C^{2′})iridium(III)acetylacetonate (abbreviation: Ir(ppy)₂(acac)); bis(1,2-diphenyl-1H-benzhnidazolato)iridium(III)acetylacetonate (abbreviation: Ir(pbi)₂(acac)); bis(benzo[h]quinolinato)iridium(III)acetylacetonate (abbreviation: Ir(bzq)₂(acac)); and the like. As a yellow-light-emitting material, the following can be given: bis(2,4-diphenyl-1,3-oxazolato-N,C^{2′})iridium(III)acetylacetonate (abbreviation: Ir(dpo)₂(acac)); bis[2-(4′-perfluorophenylphenyl)pyridinato-N,C^{2′}]iridium(III)acetylacetonate (abbreviation: Ir(p-PF-ph)₂(acac)); bis(2-phenylbenzothiazolato-N,C^{2′})iridium(III)acetylacetonate (abbreviation: Ir(bt)₂(acac)); and the like. As an orange-light-emitting material, the following can be given: tris(2-phenylquinolinato-N,C^{2′})iridium(III) (abbreviation: Ir(pq)₃); bis(2-phenylquinolinato-N,C^{2′})iridium(III)acetylacetonate (abbreviation: Ir(pq)₂(acac)); and the like. Examples of a red-light-emitting material include organic metal complexes, such as bis[2-(2′-benzo[4,5-α]thienyl)pyridinato-N,C^{3′})iridium(III)acetylacetonate (abbreviation: Ir(btp)₂(acac)), bis(1-phenylisoquinolinato-N,C^{2′})iridium(III)acetylacetonate (abbreviation: Ir(piq)₂(acac)), (acetylacetonato)bis[2,3-bis(4-fluorophenyl)quinoxalinato]iridium(III) (abbreviation: Ir(Fdpq)₂(acac)), 2,3,7,8,12,13,17,18-octaethyl-21H,23H-porphyrinplatinum(II) (abbreviation: PtOEP), and the like. In addition, a rare earth metal complex such as tris(acetylacetonato)(monophenanthroline)terbium(III) (abbreviation: Tb(acac)₃(Phen)); tris(1,3-diphenyl-1,3-propanedionato)(monophenanthroline)europium(III) (abbreviation: Eu(DBM)₃(Phen)); or tris[1-(2-thenoyl)-3,3,3-trifluoroacetonato](monophenanthroline)europium(III) (abbreviation: Eu(TTA)₃(Phen)) performs light emission (electron transition between different multiplicities) from a rare earth metal ion; therefore, such a rare earth metal complex can be used as the phosphorescent compound.

Examples of fluorescent compounds which can be used for the light-emitting layer 213 are as follows. For example, as a blue-light-emitting material, the following can be given: N,N′-bis[4-(9H-carbazol-9-yl)phenyl]-N,N′-diphenylstilbene-4,4′-diamine (abbreviation: YGA2S); 4-(9H-carbazol-9-yl)-4′-(10-phenyl-9-anthryl)triphenylamine (abbreviation: YGAPA); and the like. As a green-light-emitting material, the following can be given: N-(9,10-diphenyl-2-anthryl)-N,9-diphenyl-9H-carbazol-3-amine (abbreviation: 2PCAPA); N-[9,10-bis(1,1′-biphenyl-2-yl)-2-anthryl]-N,9-diphenyl-9H-carbazol-3-amine (abbreviation: 2PCABPhA); N-(9,10-diphenyl-2-anthryl)-N,N′,N′-triphenyl-1,4-phenylenediamine (abbreviation: 2DPAPA); N-[9,10-bis(1,1′-biphenyl-2-yl)-2-anthryl]-N,N′,N′-triphenyl-1,4-phenylenediamine (abbreviation: 2DPABPhA); 9,10-bis(1,1′-biphenyl-2-yl)-N-[4-(9-carbazol-9-yl)phenyl]-N-phenylanthracen-2-amine (abbreviation: 2YGABPhA); N,N,9-triphenylanthracen-9-amine (abbreviation: DPhAPhA); and the like. As a yellow-light-emitting material, the following can be given: rubrene; 5,12-bis(1,1′-biphenyl-4-yl)-6,11-diphenyltetracene (abbreviation: BPT); and the like. As a red-light-emitting material, the following can be given: N,N,N′,N′-tetrakis(4-methylphenyl)tetracene-5,11-diamine (abbreviation: p-mPhTD); 7,13-diphenyl-N,N,N′,N′-tetrakis(4-methylphenyl)acenaphtho[1,2-a]fluoranthene-3,10-diamine (abbreviation: p-mPhAFD); and the like.

The light-emitting layer 213 may have a structure in which a substance having a high light-emitting property (a dopant material) is dispersed in another substance (a host material), whereby crystallization of the light-emitting layer can be suppressed. Further, concentration quenching due to high concentration of the substance having a high light-emitting property can be suppressed.

As the substance in which the substance having a high light-emitting property is dispersed, when the substance having a high light-emitting property is a fluorescent compound, a substance having higher singlet excitation energy (the energy difference between a ground state and a singlet excited state) than the fluorescent compound is preferably used. When the substance having a high light-emitting property is a phosphorescent compound, a substance having higher triplet excitation energy (the energy difference between a ground state and a triplet excited state) than the phosphorescent compound is preferably used.

Examples of host materials used for the light-emitting layer 213 are given below: 4,4′-bis[N-(1-naphthyl)-N-phenylamino]biphenyl (abbreviation: NPB); tris(8-quinolinolato)aluminum(III) (abbreviation: Alq); 4,4′-bis[N-(9,9-dimethylfluoren-2-yl)-N-phenylamino]biphenyl (abbreviation: DFLDPBi); bis(2-methyl-8-quinolinolato)(4-phenylphenolato)aluminum(III) (abbreviation: BAlq); 4,4′-di(9-carbazolyl)biphenyl (abbreviation: CBP); 2-tert-butyl-9,10-di(2-naphthyl)anthracene (abbreviation: t-BuDNA); 9-[4-(9-carbazolyl)phenyl]-10-phenylanthracene (abbreviation: CzPA); and the like.

As the dopant material, any of the above-mentioned phosphorescent compounds and fluorescent compounds can be used.

When the light-emitting layer 213 has a structure in which a substance having a high light-emitting property (a dopant material) is dispersed in another substance (a host material), a mixed layer of a host material and a dopant material is formed as the material layer over the donor substrate. Alternatively, the material layer over the donor substrate may have a structure in which a layer containing a host material and a layer containing a dopant material are stacked. By forming the light-emitting layer 213 using a donor substrate with the material layer having such a structure, the light-emitting layer 213 contains a substance in which a light-emitting material is dispersed (a host material) and a substance having a high light-emitting property (a dopant material), and has a structure in which the substance having a high light-emitting property (the dopant material) is dispersed in the substance in which a light-emitting material is dispersed (the host material). Note that for the light-emitting layer 213, two or more kinds of host materials and a dopant material may be used, or two or more kinds of dopant materials and a host material may be used. Alternatively, two or more kinds of host materials and two or more kinds of dopant materials may be used.

In the case where the light-emitting element illustrated in FIG. 4 is formed, donor substrates (see Embodiment 1), each of which has a material layer formed using the materials for forming their respective layers (the hole-injecting layer 211, the hole-transporting layer 212, the electron-transporting layer 214, and the electron-injecting layer 215) in the material layer 106, are prepared for their respective layers, and with the donor substrates used for deposition of their respective layers, the material layer 106 (the hole-injecting layer 211, the hole-transporting layer 212, the electron-transporting layer 214, or the electron-injecting layer 215) can be formed over the first electrode 202 over the substrate 101 by the method described in Embodiment 1. Then, the second electrode 204 is formed over the material layer 106, whereby the light-emitting element illustrated in FIG. 4 can be obtained. Note that although all the layers of the hole-injecting layer 211, the hole-transporting layer 212, the electron-transporting layer 214, and the electron-injecting layer 215 in the material layer 106 can be formed by the method described in Embodiment 1 in this case, only some of the layers in the material layer 106 may be formed by the method described in Embodiment 1.

Alternatively, the material layer 106 having all of the hole-injecting layer 211, the hole-transporting layer 212, the electron-transporting layer 214, and the electron-injecting layer 215 is stacked over the donor substrate 102, and laser beam irradiation is performed, whereby the material layer 106 may be formed over the first electrode 202 over the substrate 101 at a time.

Further alternatively, in a similar manner to the manufacturing process illustrated in FIGS. 10A to 10E, FIGS. 11A to 11E, FIGS. 12A to 12E, or FIGS. 13A to 13E, the first electrode 202 or the second electrode 204, or both the first electrode 202 and the second electrode 204 may be formed over the donor substrate 102 with the material layer 106, and then, laser beam irradiation is performed, whereby the first electrode 202 or the second electrode 204, or both the first electrode 202 and the second electrode 204, and the material layer 106 may be formed over the substrate 101.

For example, the hole-injecting layer 211 can be formed using molybdenum oxide, vanadium oxide, ruthenium oxide, tungsten oxide, manganese oxide, or the like. In addition, it is possible to use a phthalocyanine-based compound such as phthalocyanine (abbreviation: H₂Pc) or copper phthalocyanine (abbreviation: CuPc), a high molecule such as poly(3,4-ethylenedioxythiophene)/poly(styrenesulfonic acid) (PEDOT/PSS), or the like to form the hole-injecting layer.

Alternatively, as the hole-injecting layer 211, a layer which contains a substance having a high hole-transporting property and a substance having an electron-accepting property can be used. The layer which contains a substance having a high hole-transporting property and a substance having an electron-accepting property has a high carrier density and an excellent hole-injecting property. In addition, the layer which contains a substance having a high hole-transporting property and a substance having an electron-accepting property is used as a hole-injecting layer that is in contact with an electrode which functions as an anode, whereby various kinds of metals, alloys, electrically conductive compounds, mixtures thereof, and the like can be used regardless of the work function of a material of the electrode which functions as an anode.

The layer which contains a substance having a high hole-transporting property and a substance having an electron-accepting property can be formed using, for example, a donor substrate having a material layer in which a layer that contains a substance having a high hole-transporting property and a layer that contains a substance having an electron-accepting property are stacked.

As the substance having an electron-accepting property, which is used for the hole-injecting layer 211, 7,7,8,8-tetracyano-2,3,5,6-tetrafluoroquinodimethane (abbreviation: F4-TCNQ), chloranil, and the like can be given. In addition, transition metal oxide can be given. Still other examples are oxide of metal belonging to Group 4 to Group 8 of the periodic table. Specifically, vanadium oxide, niobium oxide, tantalum oxide, chromium oxide, molybdenum oxide, tungsten oxide, manganese oxide, and rhenium oxide are preferable because of a high electron-accepting property. Among these, molybdenum oxide is especially preferable since it is stable in the air and its hygroscopic property is low so that it can be easily treated.

As the substance having a high hole-transporting property used for the hole-injecting layer 211, any of various compounds such as an aromatic amine compound, a carbazole derivative, an aromatic hydrocarbon, and a high molecular compound (such as oligomer, dendrimer, and polymer) can be used. A substance having a hole mobility of greater than or equal to 10⁻⁶ cm²/Vs is preferably used as a substance having a high hole-transporting property used for the hole-injecting layer. However, any substance other than the above substances may also be used as long as it is a substance in which the hole-transporting property is higher than the electron-transporting property. Specific examples of the substance having a high hole-transporting property, which can be used for the hole-injecting layer 211, are given below.

Examples of aromatic amine compounds that can be used for the hole-injecting layer 211 include: 4,4′-bis[N-(1-naphthyl)-N-phenylamino]biphenyl (abbreviation: NPB); N,N′-bis(3-methylphenyl)-N,N′-diphenyl-[1,1′-biphenyl]-4,4′-diamine (abbreviation: TPD); 4,4′,4″-tris(N,N-diphenylamino)triphenylamine (abbreviation: TDATA); 4,4′,4″-tris[N-(3-methylphenyl)-N-phenylamino]triphenylamine (abbreviation: MTDATA); 4,4′-bis[N-(spiro-9,9′-bifluoren-2-yl)-N-phenylamino]-1,1′-biphenyl (abbreviation: BSPB); and the like. In addition, the following can be given: N,N′-bis(4-methylphenyl)(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), and the like.

As a carbazole derivative which can be used for the hole-injecting layer 211, the following can be given specifically: 3-[N-(9-phenylcarbazol-3-yl)-N-phenylamino]-9-phenylcarbazole (abbreviation: PCzPCA1); 3,6-bis[N-(9-phenylcarbazol-3-yl)-N-phenylamino]-9-phenylcarbazole (abbreviation: PCzPCA2); 3-[N-(1-naphthyl)-N-(9-phenylcarbazol-3-yl)amino]-9-phenylcarbazole (abbreviation: PCzPCN1); and the like.

Other examples of carbazole derivatives that can be used for the hole-injecting layer 211 include: 4,4′-di(N-carbazolyl)biphenyl (abbreviation: CBP); 1,3,5-tris[4-(N-carbazolyl)phenyl]benzene (abbreviation: TCPB); 9-[4-(10-phenyl-9-anthryl)phenyl]-9H-carbazole (abbreviation: CzPA); 1,4-bis[4-(N-carbazolyl)phenyl]-2,3,5,6-tetraphenylbenzene; and the like.

Examples of the aromatic hydrocarbons that can be used for the hole-injecting layer 211 include: 2-tert-butyl-9,10-di(2-naphthyl)anthracene (abbreviation: t-BuDNA); 2-tert-butyl-9,10-di(1-naphthyl)anthracene; 9,10-bis(3,5-diphenylphenyl)anthracene (abbreviation: DPPA); 2-tert-butyl-9,10-bis(4-phenylphenyl)anthracene (abbreviation: t-BuDBA); 9,10-di(2-naphthyl)anthracene (abbreviation: DNA); 9,10-diphenylanthracene (abbreviation: DPAnth); 2-tert-butylanthracene (abbreviation: t-BuAnth); 9,10-bis(4-methyl-1-naphthyl)anthracene (abbreviation: DMNA); 9,10-bis[2-(1-naphthyl)phenyl]-2-tert-butylanthracene; 9,10-bis[2-(1-naphthyl)phenyl]anthracene; 2,3,6,7-tetramethyl-9,10-di(1-naphthyl)anthracene; 2,3,6,7-tetramethyl-9,10-di(2-naphthyl)anthracene; 9,9′-bianthryl; 10,10′-diphenyl-9,9′-bianthryl; 10,10′-bis(2-phenylphenyl)-9,9′-bianthryl; 10,10′-bis[(2,3,4,5,6-pentaphenyl)phenyl]-9,9′-bianthryl; anthracene; tetracene; rubrene; perylene; 2,5,8,11-tetra(tert-butyl)perylene; and the like. In addition, pentacene, coronene, or the like can also be used. As these aromatic hydrocarbons listed here, an aromatic hydrocarbon having hole mobility of greater than or equal to 1×10⁻⁶ cm²/Vs and having 14 to 42 carbon atoms is more preferable.

Note that an aromatic hydrocarbon that can be used for the hole-injecting layer 211 may have a vinyl skeleton. As an aromatic hydrocarbon having a vinyl group, for example, 4,4′-bis(2,2-diphenylvinyl)biphenyl (abbreviation: DPVBi), 9,10-bis[4-(2,2-diphenylvinyl)phenyl]anthracene (abbreviation: DPVPA), and the like can be given.

The hole-injecting layer 211 can be formed by using a donor substrate having a material layer in which a layer that contains a substance having a high hole-transporting property and a layer that contains a substance having an electron-accepting property are stacked. When metal oxide is used as the substance having an electron-accepting property, it is preferable that a layer containing the metal oxide be formed after the layer which contains a substance having a high hole-transporting property is formed over the substrate 101. This is because, in many cases, metal oxide is evaporated at a higher temperature than a substance having a high hole-transporting property. The donor substrate with such a structure makes it possible to efficiently deposit a substance having a high hole-transporting property and metal oxide. In addition, local non-uniformity of the concentration in a deposited film can be suppressed. Moreover, there are few kinds of solvents which dissolve or disperse both a substance having a high hole-transporting property and metal oxide, and a mixed solution is not easily formed. Therefore, it is difficult to directly form a mixed layer by a wet method. However, the use of the deposition method of this embodiment makes it possible to easily form a mixed layer which contains a substance having a high hole-transporting property and metal oxide.

In addition, the layer which contains a substance having a high hole-transporting property and a substance having an electron-accepting property is excellent in not only a hole-injecting property but also a hole-transporting property, and thus the above-described hole-injecting layer 211 may be used as the hole-transporting layer.

The hole-transporting layer 212 contains a substance having a high hole-transporting property. As the substance having a high hole-transporting property, for example, there are aromatic amine compounds such as 4,4′-bis[N-(1-naphthyl)-N-phenylamino]biphenyl (abbreviation: NPB), N,N-bis(3-methylphenyl)-N,N′-diphenyl-[1,1′-biphenyl]-4,4′-diamine (abbreviation: TPD), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluoren-2-yl)-N-phenylamino]-1,1′-biphenyl (abbreviation: BSPB), and the like. The materials described here are mainly materials having hole mobility of greater than or equal to 10⁻⁶ cm²/Vs. However, any substance other than the above substances may also be used as long as it is a substance in which the hole-transporting property is higher than the electron-transporting property. Note that the layer which contains a substance having a high hole-transporting property is not limited to a single layer, and two or more layers containing the above substances may be stacked.

The electron-transporting layer 214 is a layer which contains a substance having a high electron-transporting property. Examples thereof are given below: metal complexes having a quinoline skeleton or a benzoquinoline skeleton, such as tris(8-quinolinolato)aluminum (abbreviation: Alq), tris(4-methyl-8-quinolinolato)aluminum (abbreviation: Almq₃), bis(10-hydroxybenzo[h]quinolinato)beryllium (abbreviation: BeBq₂), and bis(2-methyl-8-quinolinolato)(4-phenylphenolato)aluminum: (abbreviation: BAlq). Alternatively, a metal complex having an oxazole-based or thiazole-based ligand, such as bis[2-(2-hydroxyphenyl)benzoxazolato]zinc (abbreviation: Zn(BOX)₂) or bis[2-(2-hydroxyphenyl)benzothiazolato]zinc (abbreviation: Zn(BTZ)₂) can be used. Besides the metal complexes, 2-(4-biphenylyl)-5-(4-tert-butylphenyl)-1,3,4-oxadiazole (abbreviation: PBD), 1,3-bis[5-[(β-tert-butylphenyl)-1,3,4-oxadiazol-2-yl]benzene (abbreviation: OXD-7), 3-(4-biphenylyl)-4-phenyl-5-(4-tert-butylphenyl)-1,2,4-triazole (abbreviation: TAZ01), bathophenanthroline (abbreviation: BPhen), bathocuproine (abbreviation: BCP), or the like can also be used. The materials described here are mainly materials having electron mobility of greater than or equal to 10⁻⁶ cm²/Vs. Note that a substance other than the above substances may be used as the electron-transporting layer as long as it has a higher electron-transporting property than a hole-transporting property. Further, the electron-transporting layer may be formed by not only a single layer but also a stacked film in which two or more layers made from the above substances are stacked.

As the electron-injecting layer 215, a compound of an alkali metal or an alkaline earth metal such as lithium fluoride (LiF), cesium fluoride (CsF), or calcium fluoride (CaF₂) can be used. Furthermore, a layer, in which a substance having an electron-transporting property is combined with an alkali metal or an alkaline earth metal, can be used. For example, Alq in which magnesium (Mg) is contained can be used. It is more preferable to use the layer in which a substance having an electron-transporting property is combined with an alkali metal or an alkaline earth metal as the electron-injecting layer because electron injection from the second electrode 204 efficiently proceeds by the use of such a layer.

Note that there is no particular limitation on a stacked structure of layers of the material layer 106. The material layer 106 may be formed by an appropriate combination of a light-emitting layer with a layer formed from a substance having a high electron-transporting property, a substance having a high hole-transporting property, a substance having a high electron-injecting property, a substance having a high hole-injecting property, a bipolar substance (a substance having high electron-transporting and hole-transporting properties), or the like.

Light emission obtained from the material layer 106 is extracted to the outside through one of or both the first electrode 202 and the second electrode 204. Accordingly, one of or both the first electrode 202 and the second electrode 204 are an electrode having a light-transmitting property. When only the first electrode 202 is a light-transmitting electrode, light is extracted from the substrate 101 side through the first electrode 202. Meanwhile, when only the second electrode 204 is a light-transmitting electrode, light is extracted from a side opposite to the substrate 101 side through the second electrode 204. When both the first electrode 202 and the second electrode 204 are light-transmitting electrodes, light is extracted from both the substrate 101 side and the side opposite to the substrate 101 side through the first electrode 202 and the second electrode 204.

Although FIGS. 14A and 14B illustrate a structure in which the first electrode 202 that functions as an anode is provided on the substrate 101 side, the second electrode 204 that functions as a cathode may be provided on the substrate 101 side.

The material layer 106 is formed by the deposition method described in Embodiment or may be formed by a combination of the deposition method described in Embodiment 1 with another deposition method. Further, each electrode and each layer may be formed by different formation methods. Examples of a dry method include a vacuum evaporation method, an electron beam evaporation method, a sputtering method, and the like. Examples of a wet method include an ink-jet method, a spin coating method, and the like.

In the light-emitting element according to this embodiment, an EL layer to which one embodiment of the present invention is applied can be formed. Accordingly, a highly accurate film can be formed efficiently. Therefore, not only improvement in characteristics of the light-emitting element, but also improvement in yield and reduction in cost can be achieved.

### Embodiment 3

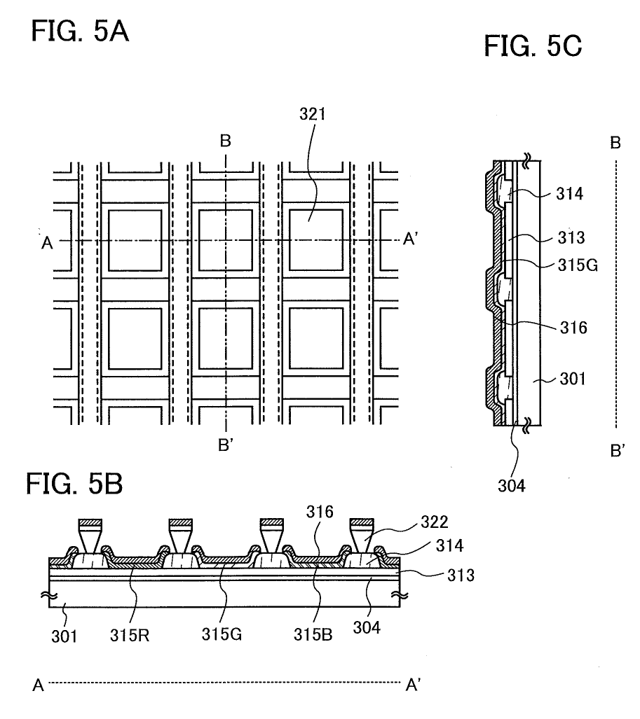

In this embodiment, a light-emitting device that is formed using any of the light-emitting elements described in Embodiment 2 will be described with reference to FIGS. 5A to 5C, FIG. 6, and FIGS. 7A and 7B.

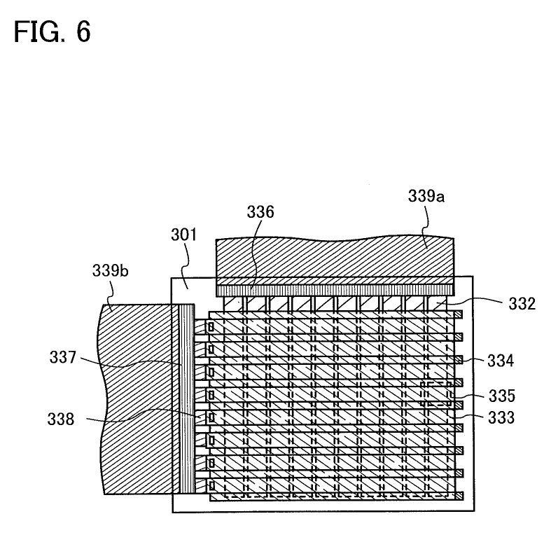

First, a passive-matrix light-emitting device will be described with reference to FIGS. 5A to 5C and FIG. 6.

In a passive-matrix (also called simple-matrix) light-emitting device, a plurality of anodes arranged in stripes (in strip form) is provided to be perpendicular to a plurality of cathodes arranged in stripes. A light-emitting layer is interposed at each intersection. Therefore, a pixel at an intersection of an anode selected (to which voltage is applied) and a cathode selected emits light.

FIG. 5A is a top view of a pixel portion before being sealed, FIG. 5B is a cross-sectional view taken along chain line A-A′ of FIG. 5A, and FIG. 5C is a cross-sectional view taken along chain line B-B′ of FIG. 5A.

Over a substrate 301, an insulating layer 304 is formed as a base insulating layer. Note that the insulating layer 304 is not necessarily formed if the base insulating layer is not needed. A plurality of first electrodes 313 is arranged in stripes at regular intervals over the insulating layer 304. A partition 314 having openings corresponding to their respective pixels is provided over the first electrodes 313. The partition 314 having openings is formed using an insulating material (a photosensitive or nonphotosensitive organic material (polyimide, acrylic, polyamide, polyimide amide, resist, or benzocyclobutene) or an SOG film (such as a silicon oxide film including an alkyl group)). Note that openings each corresponding to the pixel become light-emitting regions 321.

Over the partition 314 having openings, a plurality of inversely tapered partitions 322 parallel to each other is provided to intersect the first electrodes 313. The inversely tapered partitions 322 are formed by a photolithography method using a positive photosensitive resin and controlling the amount of light exposure or developing time in such a manner that a portion below the positive photosensitive resin is etched more.

The total thickness of the partition 314 having openings and each of the inversely tapered partitions 322 is set to be larger than the total thickness of each of EL layers 315 (an EL layer 315R, an EL layer 315G, and an EL layer 315B) and each of second electrodes 316. Thus, the EL layers 315 that are divided into a plurality of regions, specifically, an EL layer (R) (the EL layer 315R) formed from a material exhibiting red light emission, an EL layer (G) (the EL layer 315G) formed from a material exhibiting green light emission, and an EL layer (B) (the EL layer 315B) formed from a material exhibiting blue light emission; and the second electrodes 316 are formed. Note that the plurality of separated regions is electrically isolated from one another.

The second electrodes 316 are striped electrodes which are provided in parallel and extend in a direction to intersect the first electrodes 313. Note that the EL layers 315 and a part of conductive layers forming the second electrodes 316 are also formed over the inversely tapered partitions 322; however, they are separated from the EL layer (R) (the EL layer 315R), the EL layer (G) (the EL layer 315G), the EL layer (B) (the EL layer 315B), and the second electrodes 316. Note that the EL layer in this embodiment is a layer including at least a light-emitting layer and may include a hole-injecting layer, a hole-transporting layer, an electron-transporting layer, an electron-injecting layer, or the like in addition to the light-emitting layer.

Here, an example is described in which the EL layer (R) (the EL layer 315R), the EL layer (G) (the EL layer 315G), and the EL layer (B) (the EL layer 315B) are selectively formed to form a light-emitting device that emits three kinds of lights (red (R), green (G), and blue (B)) and is capable of full color display. Note that the EL layer (R) (the EL layer 315R), the EL layer (G) (the EL layer 315G), and the EL layer (B) (the EL layer 315B) are formed into stripes parallel to one another. These EL layers 315 may be formed by the deposition method described in Embodiments 1 and 2.

Further, sealing is performed using a sealant such as a sealant can or a glass substrate for sealing, if necessary. Here, a glass substrate is used as a sealing substrate, and a substrate and the sealing substrate are attached to each other with an adhesive material such as a sealing material to seal a space surrounded by the adhesive material such as a sealing material. The space that is sealed is filled with a filler or a dried inert gas. In addition, a space between the substrate and the sealant may be filled and sealed with a desiccating agent or the like so that reliability of the light-emitting device is increased. The desiccating agent removes a minute amount of moisture for sufficient desiccation. For the desiccating agent, a substance that adsorbs moisture by chemical adsorption such as oxide of an alkaline earth metal such as calcium oxide or barium oxide can be used. Note that a substance that adsorbs moisture by physical adsorption such as zeolite or silica gel may be used.

The desiccating agent is not necessarily provided if the sealant that covers and is in contact with the light-emitting element is provided to sufficiently block the outside air.

Next, FIG. 6 illustrates a top view of the case where the passive-matrix light-emitting device illustrated in FIGS. 5A to 5C is mounted with an FPC or the like.

As illustrated in FIG. 6, in a pixel portion forming an image display, scan lines and data lines are arranged to intersect with each other so that the scan lines and the data lines are perpendicular to each other.

Here, the first electrodes 313 in FIGS. 5A to 5C correspond to scan lines 333 in FIG. 6; the second electrodes 316 in FIGS. 5A to 5C correspond to data lines 332 in FIG. 6; and the inversely tapered partitions 322 correspond to partitions 334. EL layers are sandwiched between the data lines 332 and the scan lines 333, and an intersection portion indicated by a region 335 corresponds to one pixel.

Note that the scan line 333 is electrically connected to a connecting wiring 338 at an edge of the wiring, and the connecting wiring 338 is connected to an FPC 339b via an input terminal 337. The data line is connected to an FPC 339a via an input terminal 336.

If necessary, an optical film such as a polarizing plate, a circularly polarizing plate (including an elliptically polarizing plate), a retardation plate (a quarter-wave plate or a half-wave plate), or a color filter may be provided as appropriate on the light-emission surface. Further, the polarizing plate or the circularly polarizing plate may be provided with an anti-reflection film. For example, anti-glare treatment can be performed by which reflected light can be diffused with unevenness of the surface and glare can be reduced.

Although FIG. 6 illustrates an example in which a driver circuit is not provided over the substrate, this embodiment is not particularly limited to this example. An IC chip including a driver circuit may be mounted on the substrate.

In the case where an IC chip is mounted, a data line side IC and a scan line side IC, in each of which a driver circuit for transmitting a signal to the pixel portion is formed, are mounted on the periphery of (outside of) the pixel portion by a COG method. The mounting may be performed using TCP or a wire bonding method other than the COG method. TCP is a TAB tape on which an IC is mounted, and the IC is mounted by connecting the TAB tape to wirings on the element formation substrate. Each of the data line side IC and the scan line side IC may be formed using a silicon substrate. Alternatively, the IC may be a driver circuit which is formed using a TFT over a glass substrate, a quartz substrate, or a plastic substrate. Although described here is an example in which one IC is provided on one side, a plurality of ICs may be provided on one side.

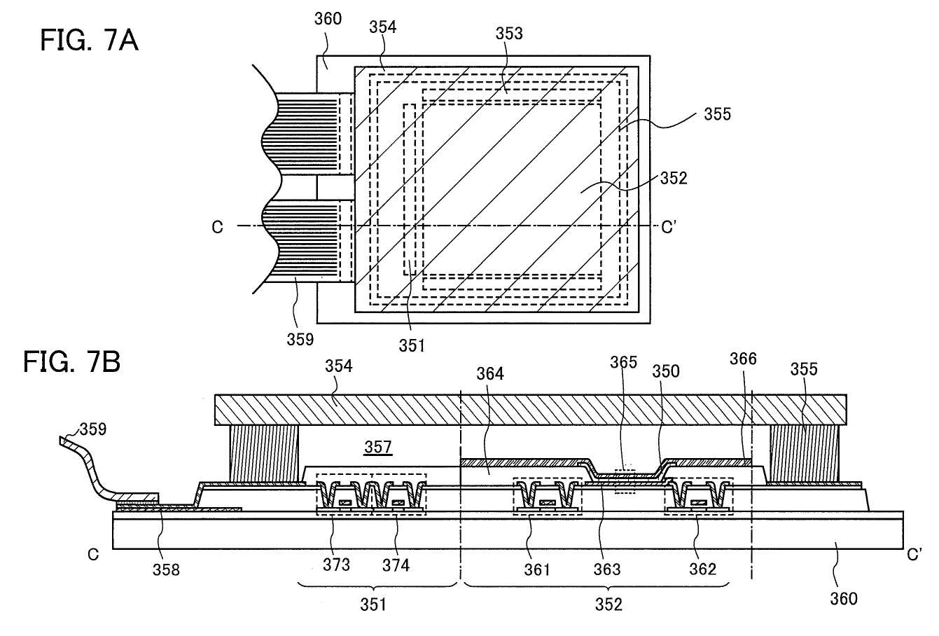

Next, an example of an active-matrix light-emitting device is described with reference to FIGS. 7A and 7B. Note that FIG. 7A is a top view illustrating a light-emitting device, and FIG. 7B is a cross-sectional view taken along chain line C-C′ in FIG. 7A. The active-matrix light-emitting device of this embodiment includes a pixel portion 352 provided over an element substrate 360, a driver circuit portion (a source side driver circuit) 351, and a driver circuit portion (a gate side driver circuit) 353. The pixel portion 352, the driver circuit portion 351, and the driver circuit portion 353 are sealed, with a sealing material 355, between the element substrate 360 and a sealing substrate 354.

In addition, over the element substrate 360, a lead wiring 358 for connecting an external input terminal which transmits a signal (e.g., a video signal, a clock signal, a start signal, or a reset signal) or potential to the driver circuit portion 351 and the driver circuit portion 353 is provided. Here, an example is described in which a flexible printed circuit (FPC) 359 is provided as the external input terminal. Although only the FPC is illustrated here, this FPC may be provided with a printed wiring board (PWB). The light-emitting device according to this specification includes not only a light-emitting device body but also a state in which an FPC or a PWB is attached thereto.

Next, a cross-sectional structure is described with reference to FIG. 7B. While the driver circuit portions 351 and 353 and the pixel portion 352 are provided over the element substrate 360, FIG. 7B illustrates the driver circuit portion 351, which is the source side driver circuit, and the pixel portion 352.

An example is illustrated in which a CMOS circuit which is the combination of an n-channel TFT 373 and a p-channel TFT 374 is formed in the driver circuit portion 351. Note that a circuit included in the driver circuit portions 351 and 353 may be formed of various CMOS circuits, PMOS circuits, or NMOS circuits. In this embodiment, although the pixel portion 352 and the driver circuit portions 351 and 353 are formed over the element substrate 360, the pixel portion 352 and the driver circuit portions 351 and 353 are not necessarily formed over the element substrate 360 and the driver circuit portions can be formed outside the element substrate 360.

The pixel portion 352 includes a plurality of pixels, each of which includes a switching TFT 361, a current-controlling TFT 362, and a first electrode 363 which is electrically connected to a wiring (a source electrode or a drain electrode) of the current-controlling TFT 362. Note that an insulator 364 is formed to cover an end portion of the first electrode 363. Here, the insulator 364 is formed using a positive photosensitive acrylic resin.

The insulator 364 is preferably formed so as to have a curved surface with curvature at an upper end portion or a lower end portion thereof in order to obtain favorable coverage by a film which is to be stacked over the insulator 364. For example, in the case of using a positive photosensitive acrylic resin as a material for the insulator 364, the insulator 364 is preferably formed so as to have a curved surface with a curvature radius (0.2 μm to 3 μm) at the upper end portion thereof. Either a negative photosensitive material which becomes insoluble in an etchant by light irradiation or a positive photosensitive material which becomes soluble in an etchant by light irradiation can be used for the insulator 364. As the insulator 364, without limitation to an organic compound, either an organic compound or an inorganic compound such as silicon oxide or silicon oxynitride can be used.

An EL layer 350 and a second electrode 366 are stacked over the first electrode 363. Note that when an ITO film is used as the first electrode 363, and a stacked film of a titanium nitride film and a film containing aluminum as its main component or a stacked film of a titanium nitride film, a film containing aluminum as its main component, and a titanium nitride film is used as a wiring of the current-controlling TFT 362 which is connected to the first electrode 363, resistance of the wiring is low and favorable ohmic contact with the ITO film can be obtained. Note that, although not illustrated here, the second electrode 366 is electrically connected to the FPC 359 which is an external input terminal.

In the EL layer 350, at least a light-emitting layer is provided, and in addition to the light-emitting layer, a hole-injecting layer, a hole-transporting layer, an electron-transporting layer, or an electron-injecting layer is provided as appropriate. The first electrode 363, the EL layer 350, and the second electrode 366 are stacked, whereby a light-emitting element 365 is formed.

The EL layer 350 may be formed by the deposition method described in Embodiments 1 and 2.

Although the cross-sectional view of FIG. 7B illustrates only one light-emitting element 365, a plurality of light-emitting elements is arranged in matrix in the pixel portion 352. Light-emitting elements which provide three kinds of light emissions (R, G, and B) are selectively formed in the pixel portion 352, whereby a light-emitting device which is capable of full color display can be formed. Alternatively, by a combination with color filters, a light-emitting device capable of full color display may be formed.

By attaching the sealing substrate 354 to the element substrate 360 with the sealing material 355, the light-emitting element 365 is provided in a space 357 surrounded by the element substrate 360, the sealing substrate 354, and the sealing material 355. Note that there are cases where the space 357 is filled with the sealing material 355 as well as an inert gas (nitrogen, argon, or the like).

Note that an epoxy-based resin is preferably used as the sealing material 355. It is preferable that such a material transmit as little moisture or oxygen as possible. As the sealing substrate 354, a plastic substrate formed from fiberglass-reinforced plastics (FRP), polyvinyl fluoride (PVF), polyester, acrylic, or the like can be used instead of a glass substrate or a quartz substrate.

As described above, the light-emitting device can be obtained by application of one embodiment of the present invention. Since TFTs are manufactured in an active-matrix light-emitting device, manufacturing cost per light-emitting device tends to be high; however, the application of one embodiment of the present invention makes it possible to drastically reduce loss of materials in forming light-emitting elements. Thus, a reduction in manufacturing cost can be achieved.

According to one embodiment of the present invention, formation of an EL layer forming a light-emitting element can be facilitated as well as manufacture of a light-emitting device including the light-emitting element. In addition, it becomes possible to form a flat even film and a minute pattern; thus, a high-definition light-emitting device can be obtained.

Note that the structure described in this embodiment can be combined with the structure in any of Embodiments 1 and 2 as appropriate.

### Embodiment 4

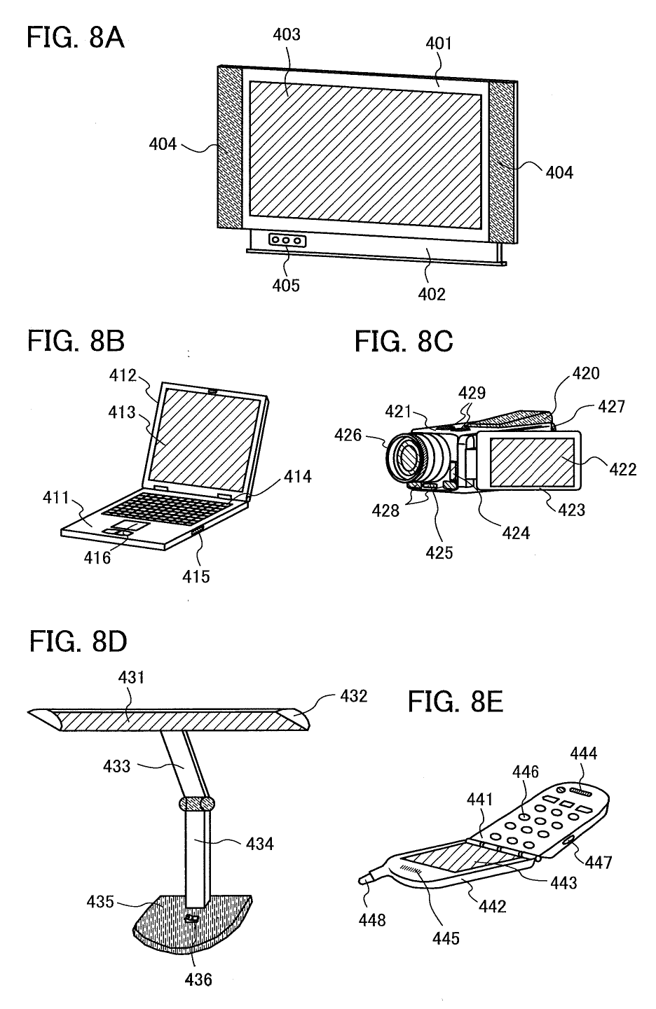

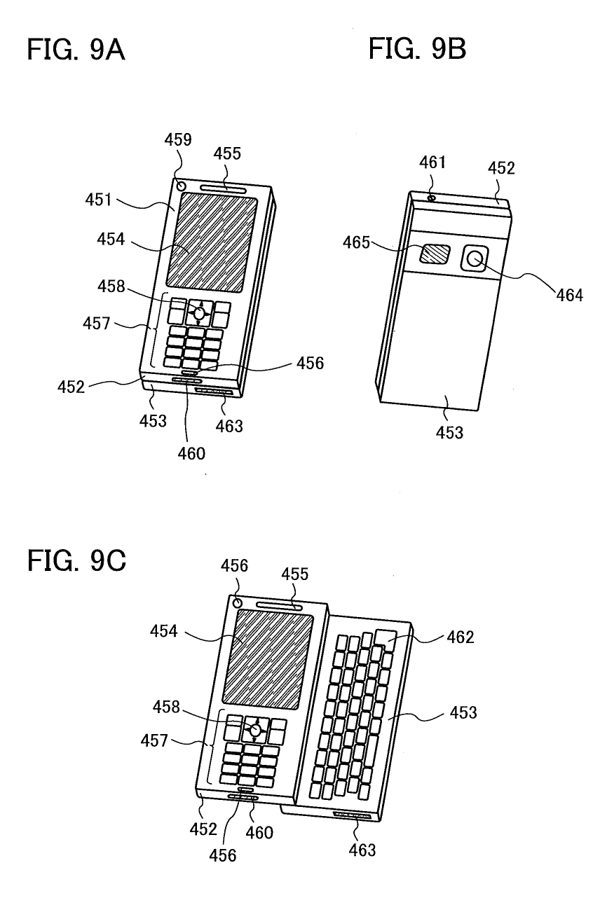

In this embodiment, various electronic devices each of which is completed using the light-emitting device manufactured by application of one embodiment of the present invention will be described with reference to FIGS. 8A to 8E and FIGS. 9A to 9C.

As examples of electronic devices to which the light-emitting device of one embodiment of the present invention is applied, there are televisions, cameras such as video cameras or digital cameras, goggle type displays (head-mounted displays), navigation systems, audio playback devices (e.g., car audio systems and audio systems), notebook computers, game machines, portable information terminals (e.g., mobile computers, cellular phones, portable game machines, and e-book readers), image playback devices in which a recording medium is provided (specifically, devices that are capable of playing back recording media such as digital versatile discs (DVDs) and equipped with a display device that can display an image), lighting appliance, and the like.

FIG. 8A illustrates a display device which includes a chassis 401, a supporting stand 402, a display portion 403, speaker portions 404, a video input terminal 405, and the like. The display device is manufactured using the light-emitting device which is formed according to one embodiment of the present invention for the display portion 403. Note that the display device includes all devices for displaying information such as for a computer, for receiving TV broadcasting, and for displaying an advertisement.

A display device provided with a display portion having high emission efficiency can be provided by applying one embodiment of the present invention.

FIG. 8B illustrates a computer which includes a main body 411, a chassis 412, a display portion 413, a keyboard 414, an external connection port 415, a pointing device 416, and the like. This computer is manufactured using the light-emitting device which is formed according to one embodiment of the present invention for the display portion 413.

A computer provided with a display portion having high emission efficiency can be provided by applying one embodiment of the present invention.

FIG. 8C illustrates a video camera which includes a main body 421, a display portion 422, a chassis 423, an external connecting port 424, a remote control receiving portion 425, an image receiving portion 426, a battery 427, an audio input portion 428, operation keys 429, an eye piece portion 420, and the like. This video camera is manufactured using the light-emitting device which is formed according to one embodiment of the present invention for the display portion 422.

A video camera provided with a display portion having high emission efficiency can be provided by applying one embodiment of the present invention.

FIG. 8D illustrates a desk lamp which includes a lighting portion 431, a shade 432, an adjustable arm 433, a support 434, a base 435, and a power supply switch 436. This desk lamp is manufactured using the light-emitting device which is formed using one embodiment of the present invention for the lighting portion 431. Note that the term ‘lighting appliance’ also encompasses ceiling lights, wall lights, and the like.

A desk lamp provided with a lighting portion having high emission efficiency can be provided by applying one embodiment of the present invention.

FIG. 8E is a cellular phone which includes a main body 441, a chassis 442, a display portion 443, an audio input portion 444, an audio output portion 445, operation keys 446, an external connection port 447, an antenna 448, and the like. This cellular phone is manufactured using the light-emitting device which is formed using one embodiment of the present invention for the display portion 443.

A cellular phone provided with a display portion having high emission efficiency can be provided by applying one embodiment of the present invention.

FIGS. 9A to 9C also illustrate a cellular phone. FIG. 9A is a front view, FIG. 9B is a rear view, and FIG. 9C is a development view. A main body 451 is a so-called smartphone which has both functions of a phone and a portable information terminal, and incorporates a computer and can process a variety of data processing in addition to voice calls.

The main body 451 includes two chassis: a chassis 452 and a chassis 453. The chassis 452 includes a display portion 454, a speaker 455, a microphone 456, operation keys 457, a pointing device 458, a camera lens 459, an external connection terminal 460, an earphone terminal 461, and the like, while the chassis 453 includes a keyboard 462, an external memory slot 463, a camera lens 464, a light 465, and the like. In addition, an antenna is incorporated in the chassis 452.

Further, in addition to the above-described structure, the cellular phone may incorporate a non-contact IC chip, a small size memory device, or the like.

The display device described in Embodiments 1 to 3 can be incorporated in the display portion 454, and a display orientation can be changed as appropriate according to a usage pattern. Because the camera lens 459 is provided in the same plane as the display portion 454, the cellular phone can be used as a videophone. Further, a still image and a moving image can be taken with the camera lens 464 and the light 465 using the display portion 454 as a viewfinder. The speaker 455 and the microphone 456 can be used for video calls, recording, reproducing, and the like without being limited to voice calls.

With the operation keys 457, making and receiving calls, inputting simple information such as e-mails or the like, scrolling the screen, moving the cursor, and the like are possible. Furthermore, the chassis 452 and the chassis 453 (FIG. 9A), which are overlapped with each other, are developed by sliding as illustrated in FIG. 9C and can be used as a portable information terminal. At this time, smooth operation can be conducted using the keyboard 462 and the pointing device 458. The external connection terminal 460 can be connected to an AC adaptor and various types of cables such as a USB cable, and charging and data communication with a computer or the like are possible. Furthermore, a large amount of data can be stored and moved by inserting a recording medium into the external memory slot 463.

In addition to the above-described functions, the cellular phone may have an infrared communication function, a television receiver function, and the like.

This cellular phone is manufactured using the light-emitting device which is formed using one embodiment of the present invention for the display portion 454.

A cellular phone provided with a display portion having high emission efficiency can be provided by applying one embodiment of the present invention.

As described above, an electronic device or a lighting appliance can be obtained by using the light-emitting device according to one embodiment of the present invention. The application range of the light-emitting device of one embodiment of the present invention is so wide that the light-emitting device can be applied to electronic devices in various fields.

This application is based on Japanese Patent Application serial no. 2008-105559 filed with Japan Patent Office on Apr. 15, 2008, the entire contents of which are hereby incorporated by reference.

What is claimed is:

1. A film deposition method comprising the steps of:
making a first substrate having a light-transmitting property and a first surface provided with a light absorption layer and a material layer having a light-emitting material face a second substrate;
placing the second substrate facing the first substrate in an inner space of a vacuum jig;
reducing pressure in the inner space of the vacuum jig; and
by irradiation of light to a second surface which is a surface on a side opposite to the first surface of the first substrate, moving the material layer in a region irradiated with the light and performing film deposition over the second substrate.

2. A film deposition method comprising the steps of:
forming a light absorption layer and a material layer having a light-emitting material over a first surface of a first substrate having a light-transmitting property;
making the first surface of the first substrate over which the material layer is formed face a second substrate;
placing the second substrate facing the first substrate in an inner space of a vacuum jig;
reducing pressure in the inner space of the vacuum jig; and
by irradiation of light to a second surface which is a surface on a side opposite to the first surface of the first substrate, moving the material layer in a region irradiated with the light and performing film deposition over the second substrate.

3. The film deposition method according to claim 1, wherein a support member for decreasing a distance between the first substrate and the second substrate is provided between a lower part of the vacuum jig and the second substrate.

4. The film deposition method according to claim 2, wherein a support member for decreasing a distance between the first substrate and the second substrate is provided between a lower part of the vacuum jig and the second substrate.

5. The film deposition method according to claim 3, wherein the support member includes a spring and a protective member.

6. The film deposition method according to claim 4, wherein the support member includes a spring and a protective member.

7. A method for manufacturing a light-emitting element, comprising the steps of:
forming a light absorption layer and a material layer having a light-emitting material over a first surface of a first substrate having a light-transmitting property;
forming a first electrode over a second substrate;
making the first surface of the first substrate over which the material layer is formed face a surface of the second substrate over which the first electrode is formed;
placing the second substrate facing the first substrate in an inner space of a vacuum jig;
reducing pressure in the inner space of the vacuum jig;
by irradiation of light to a second surface which is a surface on a side opposite to the first surface of the first substrate, moving the material layer in a region irradiated with the light and performing film deposition over the first electrode of the second substrate; and
forming a second electrode over the material layer.

8. A method for manufacturing a light-emitting element, comprising the steps of:
forming a light absorption layer, a second electrode, and a material layer having a light-emitting material over a first surface of a first substrate having a light-transmitting property;
forming a first electrode over a second substrate;
making the first surface of the first substrate over which the second electrode and the material layer are formed face a surface of the second substrate over which the first electrode is formed;
placing the second substrate facing the first substrate in an inner space of a vacuum jig;
reducing pressure in the inner space of the vacuum jig; and
by irradiation of light to a second surface which is a surface on a side opposite to the first surface of the first substrate, moving the material layer in a region irradiated with the light, and forming the material layer and the second electrode over the first electrode of the second substrate.

9. A method for manufacturing a light-emitting element, comprising the steps of:
forming a light absorption layer, a first electrode, and a material layer having a light-emitting material over a first surface of a first substrate having a light-transmitting property;
making the first surface of the first substrate over which the first electrode and the material layer are formed face a second substrate;
placing the second substrate facing the first substrate in an inner space of a vacuum jig;
reducing pressure in the inner space of the vacuum jig;
by irradiation of light to a second surface which is a surface on a side opposite to the first surface of the first substrate, moving the material layer in a region irradiated with the light, and forming the first electrode and the material layer over the second substrate; and
forming a second electrode over the material layer.

10. A method for manufacturing a light-emitting element, comprising the steps of:
forming a light absorption layer, a first electrode, a material layer having a light-emitting material, and a second electrode over a first surface of a first substrate having a light-transmitting property;
making the first surface of the first substrate over which the first electrode, the material layer, and the second electrode are formed face a second substrate;
placing the second substrate facing the first substrate in an inner space of a vacuum jig;
reducing pressure in the inner space of the vacuum jig;
by irradiation of light to a second surface which is a surface on a side opposite to the first surface of the first substrate moving the material layer in a region irradiated with the light, and forming the first electrode, the material layer, and the second electrode over the second substrate.

11. The method for manufacturing a light-emitting element according to claim 7, wherein a support member for decreasing a distance between the first substrate and the second substrate is provided between a lower part of the vacuum jig and the second substrate.

12. The method for manufacturing a light-emitting element according to claim 8, wherein a support member for decreasing a distance between the first substrate and the second substrate is provided between a lower part of the vacuum jig and the second substrate.

13. The method for manufacturing a light-emitting element according to claim 9, wherein a support member for decreasing a distance between the first substrate and the second substrate is provided between a lower part of the vacuum jig and the second substrate.

14. The method for manufacturing a light-emitting element according to claim 10, wherein a support member for decreasing a distance between the first substrate and the second substrate is provided between a lower part of the vacuum jig and the second substrate.

15. The method for manufacturing a light-emitting element according to claim 11, wherein the support member includes a spring and a protective member.

16. The method for manufacturing a light-emitting element according to claim 12, wherein the support member includes a spring and a protective member.

17. The method for manufacturing a light-emitting element according to claim 13, wherein the support member includes a spring and a protective member.

18. The method for manufacturing a light-emitting element according to claim 14, wherein the support member includes a spring and a protective member.
